(19) United States
(12) Patent Application Publication
(10) Pub. No.: US 2024/0339499 A1
(43) Pub. Date: Oct. 10, 2024

(54) SILICON CARBIDE SEMICONDUCTOR DEVICE

(71) Applicant: SUMITOMO ELECTRIC INDUSTRIES, LTD., Osaka (JP)

(72) Inventors: Kosuke UCHIDA, Osaka (JP); Takeyoshi MASUDA, Osaka (JP); Yu SAITOH, Osaka (JP)

(21) Appl. No.: 18/580,785

(22) PCT Filed: Jul. 13, 2022
(86) PCT No.: PCT/JP2022/027572

§ 371 Date: Jan. 19, 2024

(30) Foreign Application Priority Data
Sep. 15, 2021 (JP) 2021-150121

(51) Int. Cl. H01L 29/06; H01L 23/528; H01L 29/16; H01L 29/78

(52) U.S. Cl. CPC H01L 29/0696; H01L 23/5283; H01L 29/1608; H01L 29/7802

(57) ABSTRACT

A silicon carbide semiconductor device includes a silicon carbide substrate, and a gate pad and a source pad provided above a first main surface. The silicon carbide substrate includes a first region including unit cells, a second region overlapping the gate pad, and a third region continuous with the second region. Each of the unit cells includes a contact region electrically connected to a body region, and a gate insulating film provided between a gate electrode and a drift region, the body region, and a source region. The second region has a first semiconductor region of the second conductivity type. The third region has a second semiconductor region of the second conductivity type. The first semiconductor region and the second semiconductor region are continuous with each other along the first main surface. The source region, the contact region, and the second semiconductor region are electrically connected to the source pad.

### TECHNICAL FIELD

The present disclosure relates to a silicon carbide semiconductor device.

This application is based on and claims priority to Japanese Patent Application No. 2021-150121, filed on Sep. 15, 2021, the entire contents of which are incorporated herein by reference.

### BACKGROUND ART

A silicon carbide semiconductor device intended to control dielectric breakdown between a gate electrode and a source electrode at a time of switching is disclosed (see Patent Document 1, for example).

### RELATED-ART DOCUMENTS

### Patent Documents

Patent Document 1: Japanese Laid-open Patent Publication No. 2017-5278

### SUMMARY OF THE INVENTION

A silicon carbide semiconductor device according to the present disclosure includes a silicon carbide substrate having a first main surface, and a gate pad and a source pad. The gate pad and the source pad are provided above the first main surface. In a plan view from a direction perpendicular to the first main surface, the silicon carbide substrate includes a first region that includes a plurality of unit cells, a second region that overlaps the gate pad, and a third region that is continuous with the second region. Each of the unit cells includes a drift region that is of a first conductivity type, a body region that is of a second conductivity type different from the first conductivity type, a source region that is provided along the first main surface, is spaced apart from the drift region by the body region, and is of the first conductivity type, a contact region that is provided along the first main surface, is electrically connected to the body region, and is of the second conductivity type, a gate electrode electrically connected to the gate pad, and a gate insulating film provided between the gate electrode and the drift region, the body region, and the source region. The second region has a first semiconductor region that is of the second conductivity type. The third region has a second semiconductor region that is of the second conductivity type. The first semiconductor region and the second semiconductor region are continuous with each other along the first main surface. The silicon carbide semiconductor device further includes an interlayer insulating film provided between the first semiconductor region and the gate pad. The source region, the contact region, and the second semiconductor region are electrically connected to the source pad.

### BRIEF DESCRIPTION OF THE DRAWINGS

FIG. 1 is a top view illustrating a silicon carbide semiconductor device according to a first embodiment;

FIG. 2 is a diagram illustrating regions in a silicon carbide substrate of the silicon carbide semiconductor device according to the first embodiment;

FIG. 3 is a top view illustrating a region 221 of FIG. 2 when a passivation film, a gate pad, and a source pad are transparently viewed;

FIG. 4 is a top view illustrating a configuration of a first main surface of the silicon carbide substrate within the region 221 of FIG. 2;

FIG. 5 is a top view illustrating a region 222 of FIG. 2 when the passivation film, the gate pad, and the source pad are transparently viewed;

FIG. 6 is a top view illustrating a region 223 of FIG. 2 when the passivation film, the gate pad, and the source pad are transparently viewed;

FIG. 7 is a top view illustrating a region 224 of FIG. 2 when the passivation film, the gate pad, and the source pad are transparently viewed;

FIG. 8 is a cross-sectional view (part 1) illustrating the silicon carbide semiconductor device according to the first embodiment;

FIG. 9 is a cross-sectional view (part 2) illustrating the silicon carbide semiconductor device according to the first embodiment;

FIG. 10 is a cross-sectional view (part 3) illustrating the silicon carbide semiconductor device according to the first embodiment;

FIG. 11 is a cross-sectional view (part 4) illustrating the silicon carbide semiconductor device according to the first embodiment;

FIG. 12 is a cross-sectional view (part 5) illustrating the silicon carbide semiconductor device according to the first embodiment;

FIG. 13 is a cross-sectional view (part 6) illustrating the silicon carbide semiconductor device according to the first embodiment;

FIG. 14 is a cross-sectional view illustrating a configuration of unit cells;

FIG. 15 is a diagram illustrating regions in a silicon carbide substrate of a silicon carbide semiconductor device according to a second embodiment;

FIG. 16 is a top view illustrating a region 222 of FIG. 15 when a passivation film, a gate pad, and a source pad are transparently viewed;

FIG. 17 is a top view illustrating a region 223 of FIG. 15 when the passivation film, the gate pad, and the source pad are transparently viewed;

FIG. 18 is a cross-sectional view illustrating the silicon carbide semiconductor device according to the second embodiment;

FIG. 19 is a top view illustrating a silicon carbide semiconductor device according to a third embodiment;

FIG. 20 is a diagram illustrating regions in a silicon carbide substrate of the silicon carbide semiconductor device according to the third embodiment;

FIG. 21 is a diagram illustrating regions in a silicon carbide substrate of a silicon carbide semiconductor device according to a fourth embodiment;

FIG. 22 is a diagram illustrating regions in a silicon carbide substrate of a silicon carbide semiconductor device according to a fifth embodiment;

FIG. 23 is a diagram illustrating regions in a silicon carbide substrate of a silicon carbide semiconductor device according to a sixth embodiment;

FIG. 24 is a diagram illustrating regions in a silicon carbide substrate of a silicon carbide semiconductor device according to a seventh embodiment;

FIG. 25 is a top view illustrating a silicon carbide semiconductor device according to an eighth embodiment;

FIG. 26 is a diagram illustrating regions in a silicon carbide substrate of the silicon carbide semiconductor device according to the eighth embodiment;

FIG. 27 is a diagram illustrating regions in a silicon carbide substrate of a silicon carbide semiconductor device according to a ninth embodiment;

FIG. 28 is a top view illustrating a silicon carbide semiconductor device according to a tenth embodiment;

FIG. 29 is a diagram illustrating regions in a silicon carbide substrate of the silicon carbide semiconductor device according to the tenth embodiment;

FIG. 30 is a top view illustrating a silicon carbide semiconductor device according to an eleventh embodiment;

FIG. 31 is a diagram illustrating regions in a silicon carbide substrate of the silicon carbide semiconductor device according to the eleventh embodiment; and

FIG. 32 is a top view illustrating a first region according to a modification.

### MODE FOR CARRYING OUT THE INVENTION

### Problems to be Solved by the Present Disclosure

In the silicon carbide semiconductor device described in Patent Document 1, electric field concentration tends to occur in an interlayer insulating film when a surge occurs. Such electric field concentration may lead to breakage.

It is an object of the present disclosure to provide a silicon carbide semiconductor device that can alleviate electric field concentration in an interlayer insulating film.

### Effects of the Present Disclosure

According to the present disclosure, electric field concentration in an interlayer insulating film can be alleviated.

Embodiments will be described below.

### Description of Embodiments of the Present Disclosure

First, embodiments of the present disclosure will be listed and described. In crystallographic description in the present specification and the drawings, an individual orientation is indicated by [ ], a group orientation is indicated by < >, an individual plane is indicated by ( ), and a group plane is indicated by { }. Additionally, a negative crystallographic index is usually expressed by placing “-” (bar) above a number; however, in the present specification, a negative sign is placed before a number.

[1] A silicon carbide semiconductor device according to an aspect of the present disclosure includes a silicon carbide substrate having a first main surface; and a gate pad and a source pad, the gate pad and the source pad being provided above the first main surface, wherein, in a plan view from a direction perpendicular to the first main surface, the silicon carbide substrate includes a first region that includes a plurality of unit cells, a second region that overlaps the gate pad, and a third region that is continuous with the second region, each of the unit cells includes a drift region that is of a first conductivity type, a body region that is of a second conductivity type different from the first conductivity type, a source region that is provided along the first main surface, is spaced apart from the drift region by the body region, and is of the first conductivity type, a contact region that is provided along the first main surface, is electrically connected to the body region, and is of the second conductivity type, a gate electrode electrically connected to the gate pad, and a gate insulating film provided between the gate electrode and the drift region, the body region, and the source region, the second region has a first semiconductor region that is of the second conductivity type, the third region has a second semiconductor region that is of the second conductivity type, the first semiconductor region and the second semiconductor region are continuous with each other along the first main surface, the silicon carbide semiconductor device further includes an interlayer insulating film provided between the first semiconductor region and the gate pad, and the source region, the contact region, and the second semiconductor region are electrically connected to the source pad.

The third region continuous with the second region is provided, and the first semiconductor region and the second semiconductor region are continuous with each other along the first main surface. Accordingly, the contact resistance between the source pad and the second semiconductor region is reduced, and even if a surge occurs, the electric field concentration in the interlayer insulating film within the second region can be reduced.

[2] In [1], the contact region and the second semiconductor region may be continuous with each other along the first main surface. In such a case, the contact region and the second semiconductor region can be easily controlled to have the same electric potential.

[3] In [1] or [2], in the plan view, the unit cells may extend in a first direction and may be arranged at a first pitch in a second direction that is perpendicular to the first direction, and a dimension of the second semiconductor region in a direction away from the second region may be greater than or equal to the first pitch. In such a case, the contact resistance between the source pad and the second semiconductor region can be easily reduced.

[4] In [3], the dimension of the second semiconductor region in the direction away from the second region may be twice or more the first pitch. In such a case, the contact resistance between the source pad and the second semiconductor region can be further reduced easily.

[5] In [3] or [4], the third region may include a fourth region located between the first region and the second region in the plan view, and a dimension, in the second direction, of the second semiconductor region within the fourth region may be greater than or equal to the first pitch. In such a case, the contact resistance between the source pad and the second semiconductor region can be further reduced easily.

[6] In [5], the dimension, in the second direction, of the second semiconductor region within the fourth region may be twice or more the first pitch. In such a case, the contact resistance between the source pad and the second semiconductor region can be further reduced easily.

[7] In [5] or [6], in the plan view, the third region may include a fifth region located on one side, in the first direction, of the second region and of the fourth region, and an area of the second semiconductor region within the fifth region may be larger than or equal to an area of the second semiconductor region within the fourth region. In such a case, the contact resistance between the source pad and the second semiconductor region can be further reduced easily.

[8] In any one of [5] to [7], in the plan view, the third region may include a sixth region located on an opposite side, in the first direction, of the second region and of the fourth region, and an area of the second semiconductor region within the sixth region may be larger than or equal to an area of the second semiconductor region within the fourth region. In such a case, the contact resistance between the source pad and the second semiconductor region can be further reduced easily.

[9] In any one of [3] to [8], the interlayer insulating film may be formed in the first region and the third region; for each of the unit cells, a first contact hole may be formed in the interlayer insulating film within the first region, the first contact hole reaching the source region and the contact region; a second contact hole may be formed in the interlayer insulating film within the third region, the second contact hole reaching the second semiconductor region; and the first contact hole and the second contact hole may be arranged at a predetermined pitch in the second direction. In such a case, micro-loading when the first contact hole and the second contact hole are formed is suppressed, and variations in characteristics is suppressed.

[10] In any one of [1] to [9], in the plan view, the silicon carbide substrate may have a rectangular shape having a first side, a second side, a third side, and a fourth side, the first side and the second side being parallel to each other, and the third side and the fourth side being perpendicular to the first side and the second side, the silicon carbide semiconductor device may further include a first gate runner extending along the first side, a second gate runner extending along the second side, and a third gate runner continuous with the first gate runner and the second gate runner and extending along the third side, the gate pad may be continuous with the first gate runner, and the second gate runner may be spaced apart from the gate pad in a direction parallel to the third side.

[11] In [10], the gate pad may include an intersection between the first gate runner and the third gate runner, and may be continuous with the first gate runner and the third gate runner. In such a case, the gate pad can be disposed in the vicinity of the corner of the silicon carbide substrate.

[12] In [10], the third gate runner may be spaced apart from the gate pad in a direction parallel to the first side. In such a case, the gate pad can be disposed apart from the corner of the silicon carbide substrate.

[13] In [12], the third region may include a seventh region located along a side, closest to the third side, of the gate pad in the plan view, and the seventh region may be continuous with the third gate runner. In such a case, the contact resistance between the source pad and the second semiconductor region can be further reduced easily.

[14] In any one of to [13], the third region may include an eighth region located along a side, closest to the second side, of the gate pad in the plan view, and the eighth region may be spaced apart from the second gate runner. In such a case, the contact resistance between the source pad and the second semiconductor region can be further reduced easily.

[15] In any one of to [13], the third region may include an eighth region located along a side, closest to the second side, of the gate pad in the plan view, and the eighth region may be continuous with the second gate runner. In such a case, the contact resistance between the source pad and the second semiconductor region can be further reduced easily.

[16] In any one of to [15], the third region may include a ninth region located along a side, closest to the fourth side, of the gate pad in the plan view. In such a case, the contact resistance between the source pad and the second semiconductor region can be further reduced easily.

[17] In any of [1] to [9], the silicon carbide substrate may have a rectangular shape having a first side, a second side, a third side, and a fourth side in the plan view; the first side and the second side being parallel to each other, and the third side and the fourth side being perpendicular to the first side and the second side; the third region may surround the gate pad in the plan view, the silicon carbide semiconductor device may further include a first gate runner extending along the first side, a second gate runner extending along the second side, and a third gate runner continuous with the first gate runner and the second gate runner and extending along the third side, and a fourth gate runner connecting the third gate runner and the gate pad. In such a case, the degree of freedom in the arrangement of the gate pad can be improved.

### Embodiments of the Present Disclosure

In the following, embodiments of the present disclosure will be described in detail; however, the present disclosure is not limited to these embodiments. In the present specification and the drawings, components having substantially the same functions or configurations are denoted by the same reference numerals, and the description thereof may be omitted. In the present specification and the drawings, an X1-X2 direction, a Y1-Y2 direction, and a Z1-Z2 direction are mutually perpendicular directions. A plane including the X1-X2 direction and the Y1-Y2 direction will be referred to as an XY-plane, a plane including the Y1-Y2 direction and the Z1-Z2 direction will be referred to as a YZ-plane, and a plane including the Z1-Z2 direction and the X1-X2 direction will be referred to as a ZX-plane. For the sake of convenience, the Z1-Z2 direction is defined as a vertical direction, a Z1 side is defined as an upper side, and a Z2 side is defined as a lower side. Further, a plan view refers to viewing an object from the Z1 side, and a shape in a plan view refers to a shape of an object as viewed from the Z1 side.

### First Embodiment

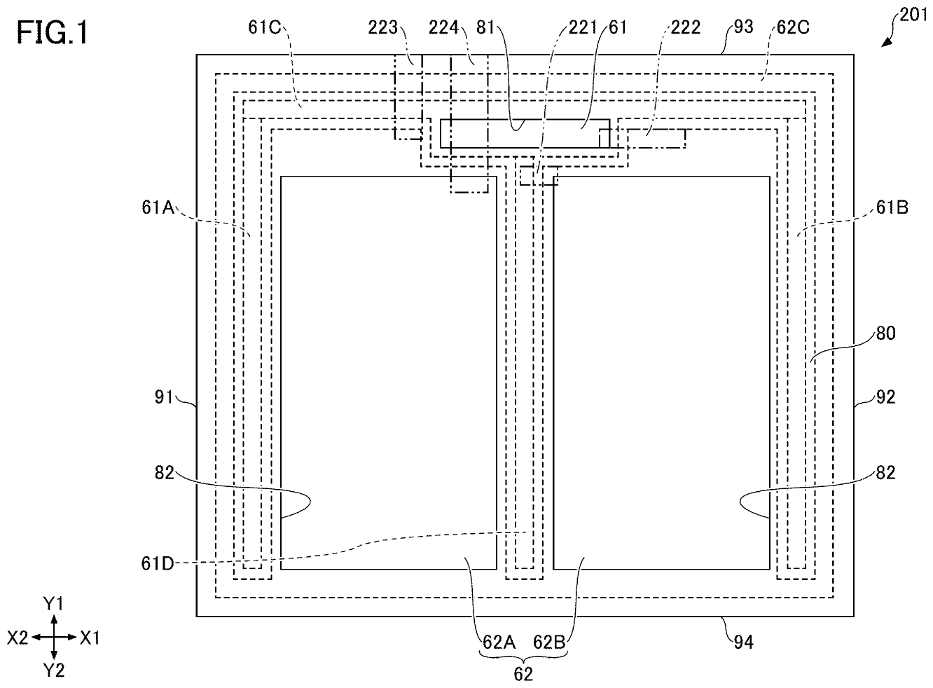

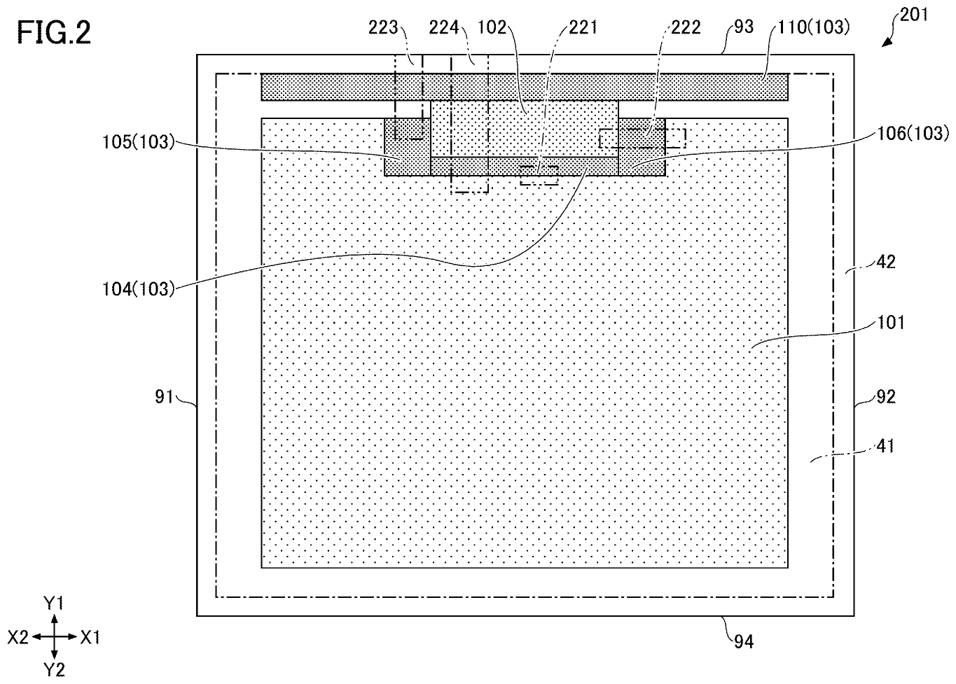

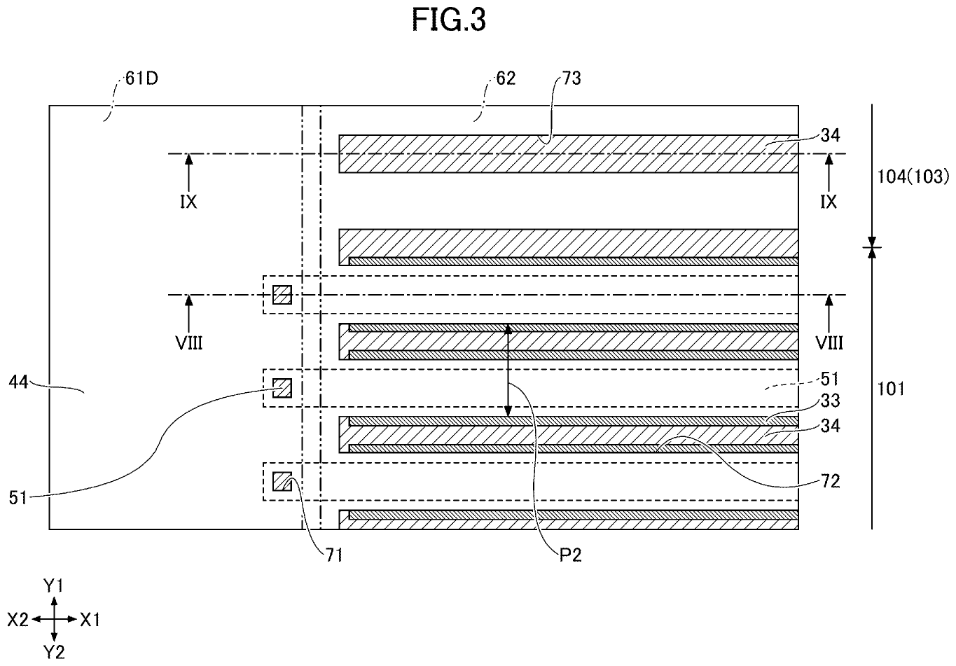

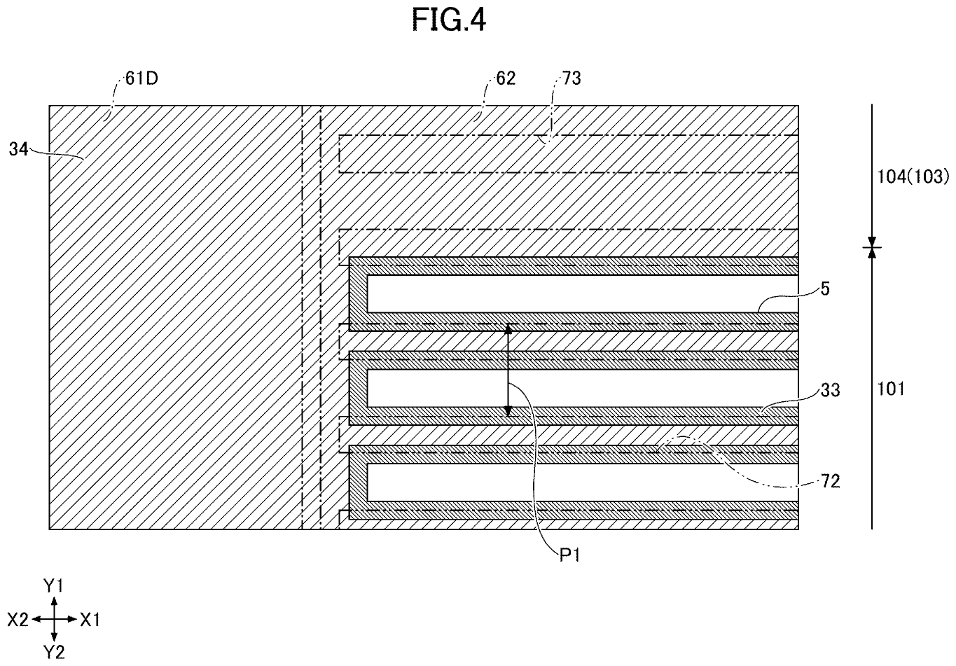

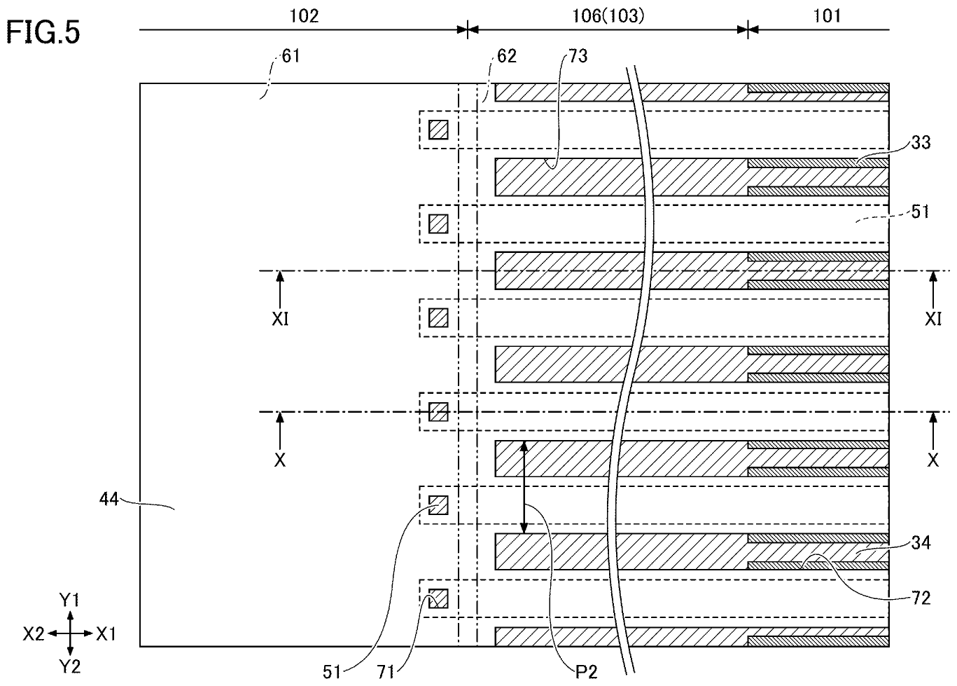

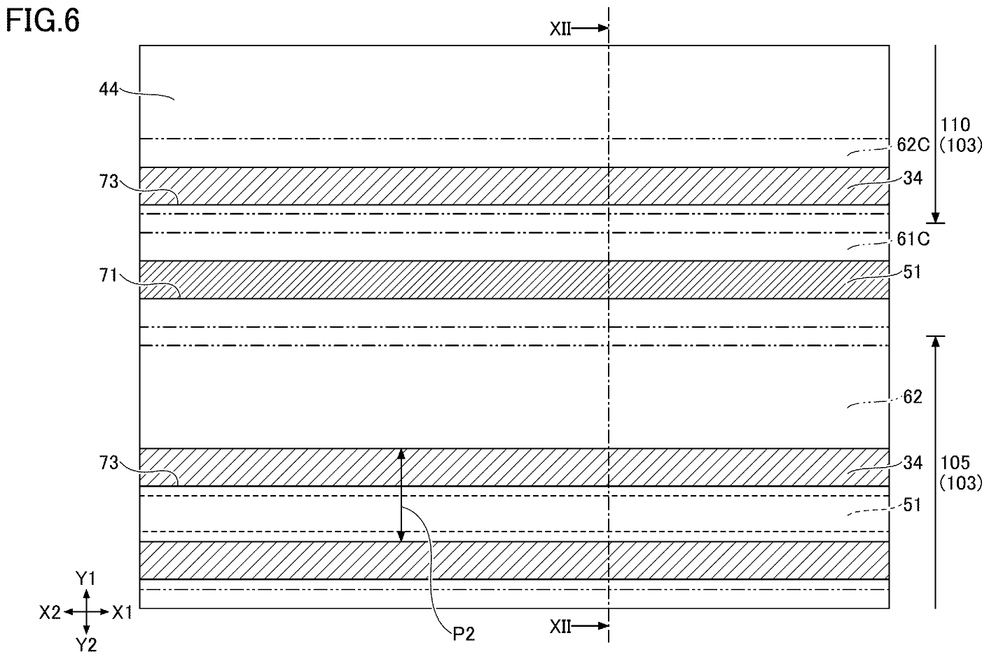

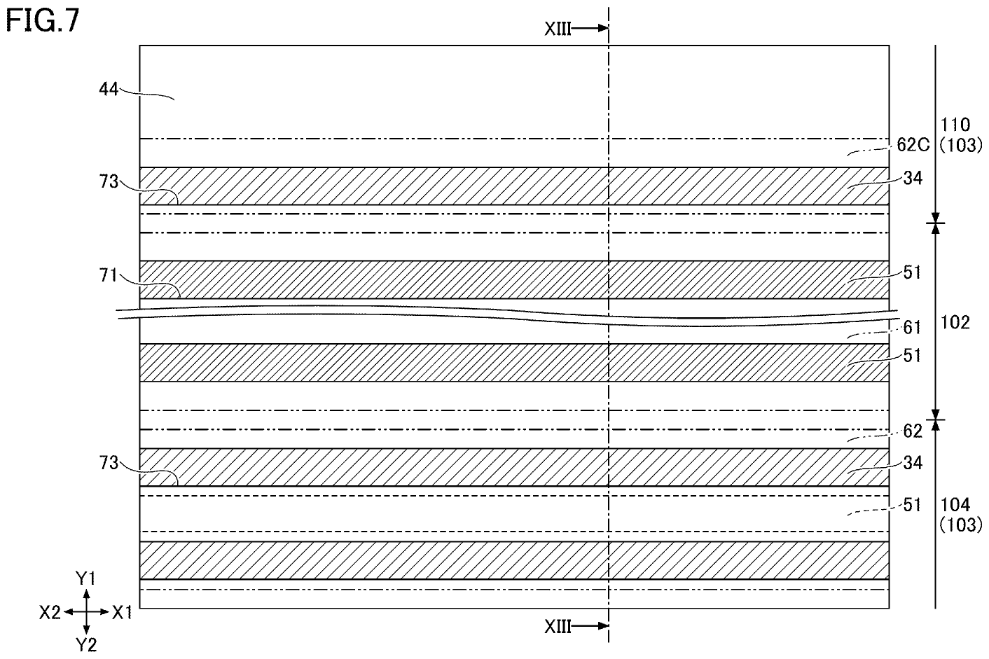

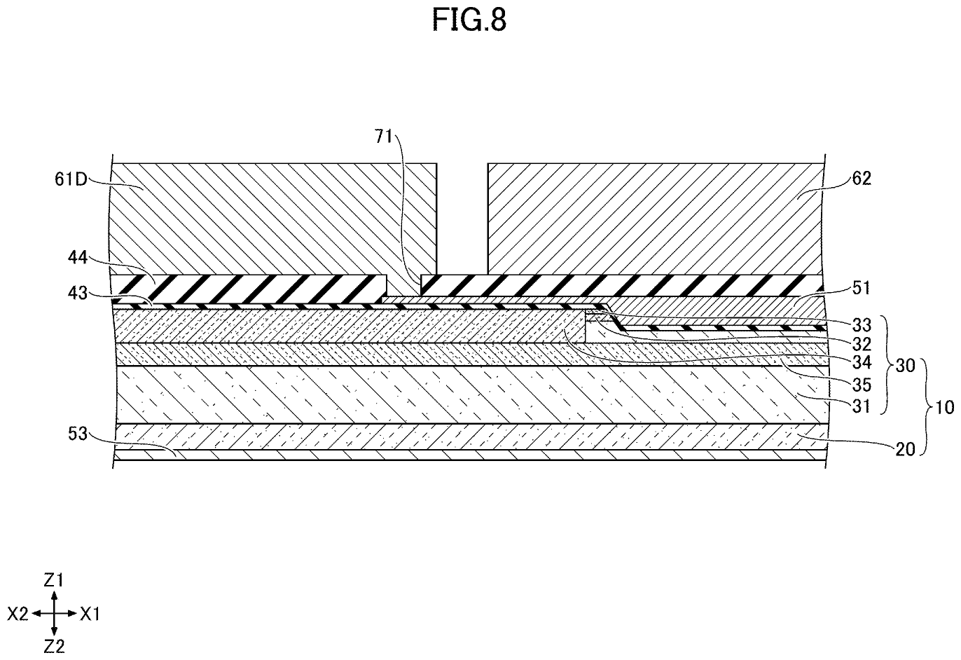

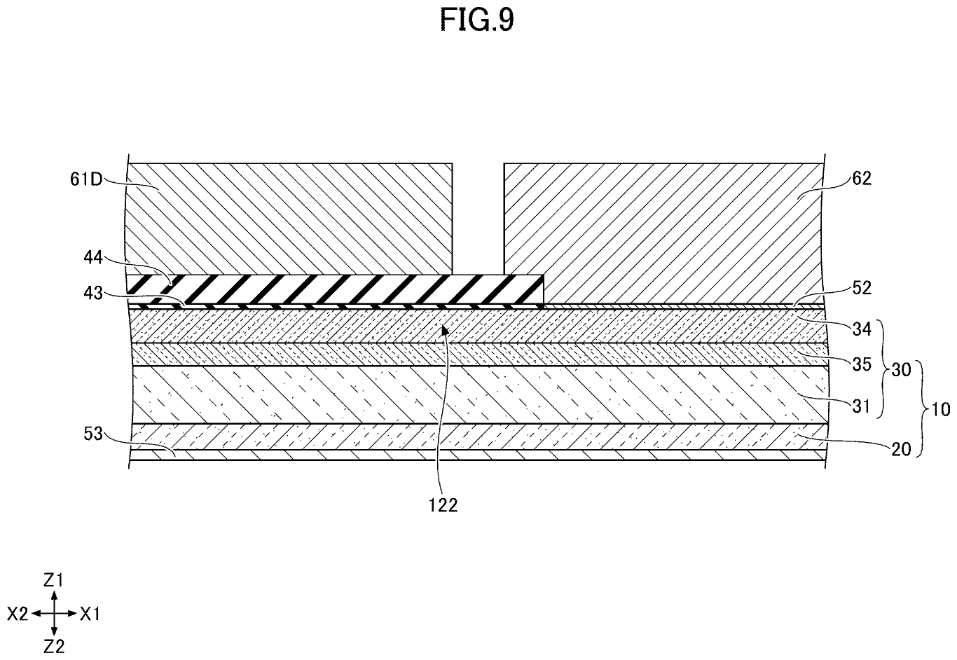

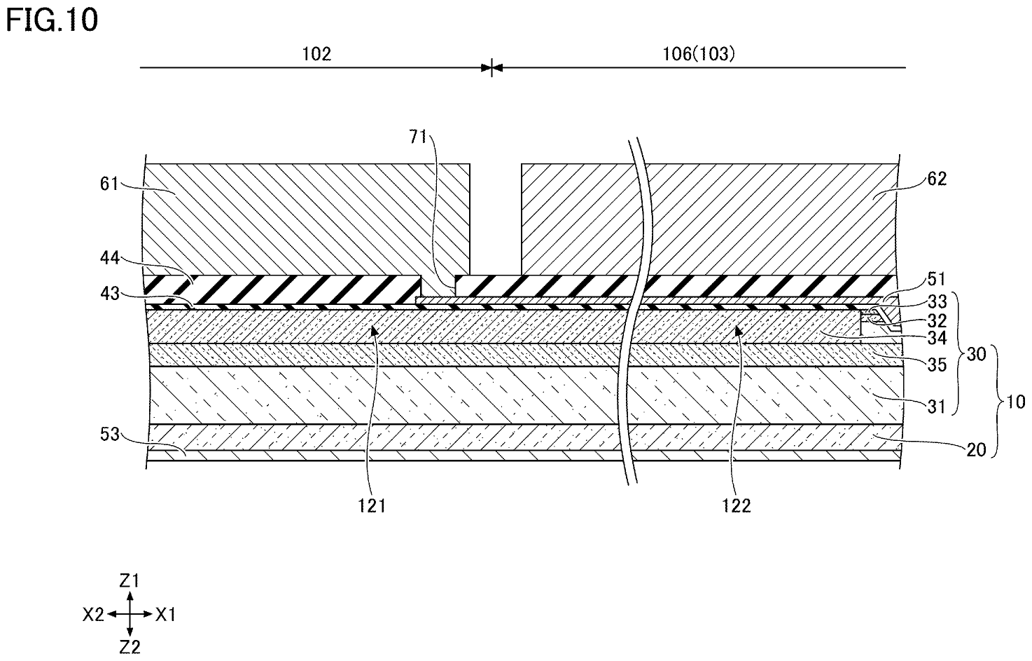

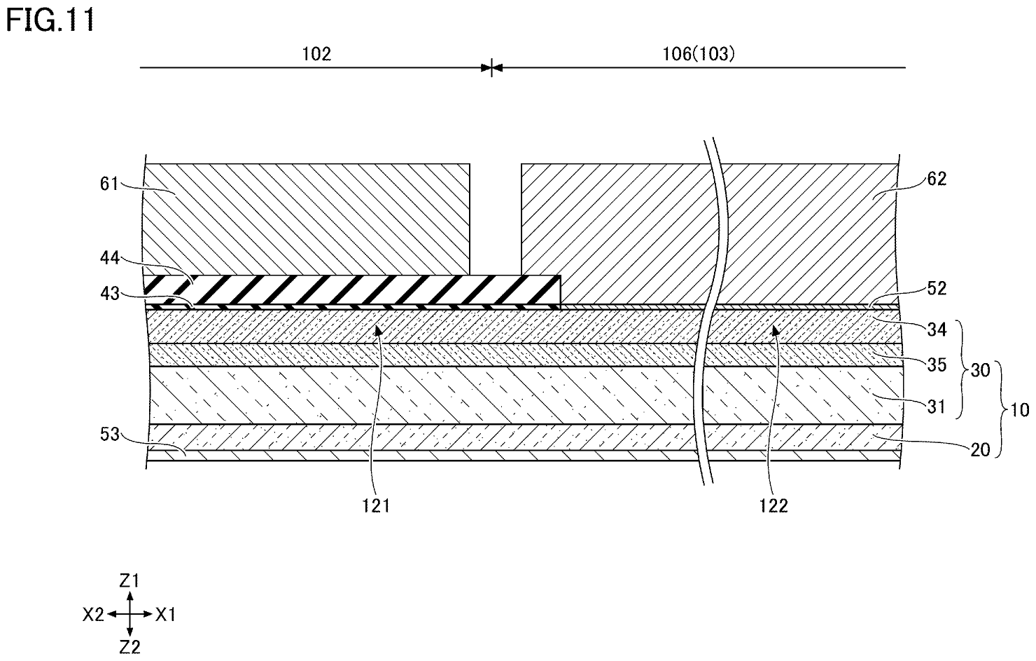

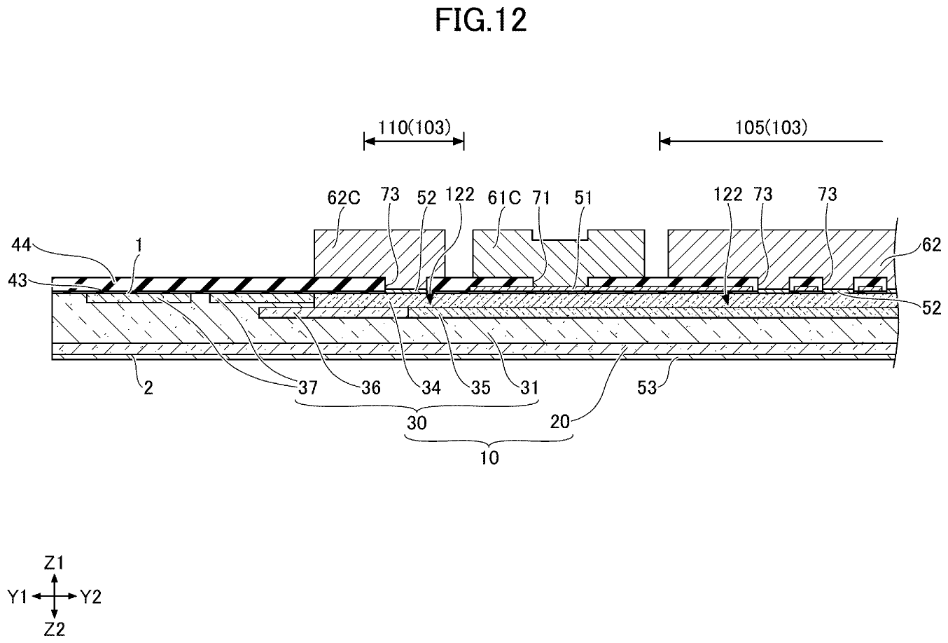

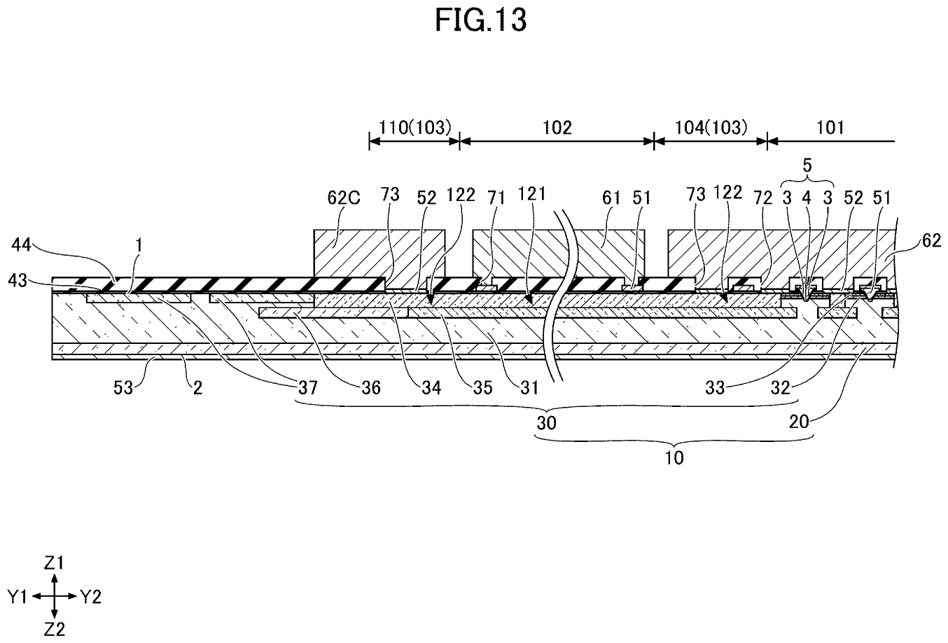

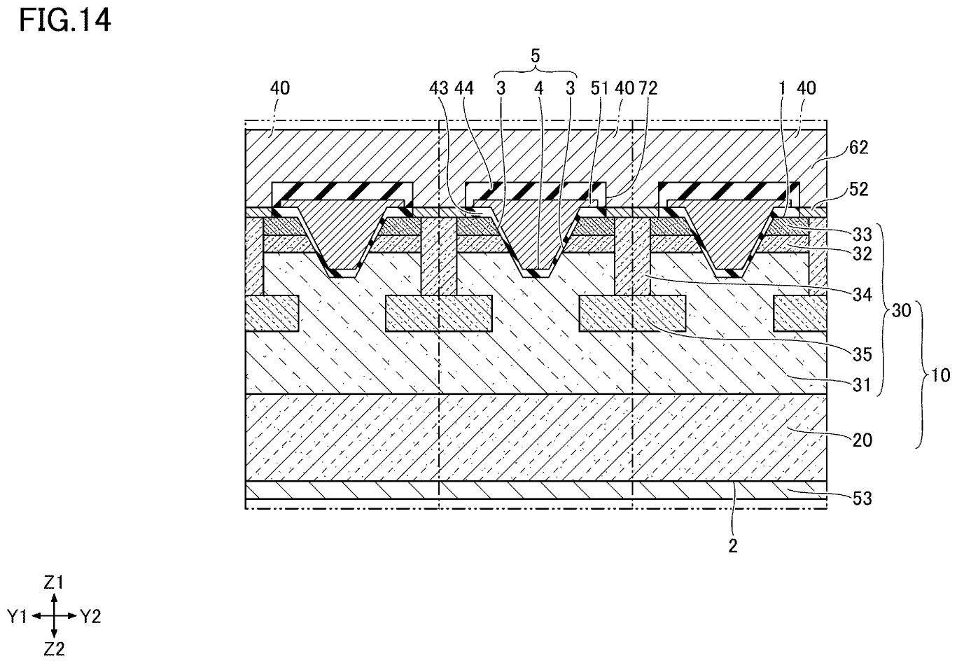

A first embodiment will be described. The first embodiment relates to what is known as a vertical metal-oxide-semiconductor field-effect transistor (MOSFET) (a silicon carbide semiconductor device). FIG. 1 is a top view illustrating the silicon carbide semiconductor device according to the first embodiment. FIG. 2 is a diagram illustrating regions in a silicon carbide substrate of the silicon carbide semiconductor device according to the first embodiment. FIG. 3 is a top view illustrating a region 221 of FIG. 2 when a passivation film, a gate pad, and a source pad are transparently viewed. FIG. 4 is a top view illustrating a configuration of a first main surface of the silicon carbide substrate within the region 221 of FIG. 2. FIG. 5 is a top view illustrating a region 222 of FIG. 2 when the passivation film, the gate pad, and the source pad are transparently viewed. FIG. 6 is a top view illustrating a region 223 of FIG. 2 when the passivation film, the gate pad, and the source pad are transparently viewed. FIG. 7 is a top view illustrating a region 224 of FIG. 2 when the passivation film, the gate pad, and the source pad are transparently viewed. FIG. 8 to FIG. 13 are cross-sectional views illustrating the silicon carbide semiconductor device according to the first embodiment. FIG. 8 corresponds to a cross-sectional view along the line VIII-VIII of FIG. 3. FIG. 9 corresponds to a cross-sectional view along the line IX-IX of FIG. 3. FIG. 10 corresponds to a cross-sectional view along the line X-X of FIG. 5. FIG. 11 corresponds to a cross-sectional view along the line XI-XI of FIG. 5. FIG. 12 corresponds to a cross-sectional view along the line XII-XII of FIG. 6. FIG. 13 corresponds to a cross-sectional view along the line XIII-XIII of FIG. 7. FIG. 14 is a cross-sectional view illustrating a configuration of unit cells. The passivation film is not depicted in FIG. 8 to FIG. 14.

As illustrated in FIG. 1 to FIG. 14, a MOSFET 201 according to the first embodiment includes a silicon carbide substrate 10, a gate insulating film 63, a gate electrode 51, an interlayer insulating film 44, a contact electrode 52, a passivation film 80, and a drain electrode 53. The MOSFET 201 further includes a gate pad 61, a source pad 62, a gate runner (gate wiring) 61A, a gate runner 61B, a gate runner 61C, a gate runner 61D, and a source runner (source wiring) 62C. The silicon carbide substrate 10 includes a silicon carbide single-crystal substrate 20 and a silicon carbide epitaxial layer 30 on the silicon carbide single-crystal substrate 20. The silicon carbide substrate 10 has a first main surface 1 and a second main surface 2 opposite to the first main surface 1. The silicon carbide epitaxial layer 30 forms the first main surface 1, and the silicon carbide single-crystal substrate 20 forms the second main surface 2. The silicon carbide single-crystal substrate 20 and the silicon carbide epitaxial layer 30 are composed of, for example, hexagonal silicon carbide of polytype 4H. The silicon carbide single-crystal substrate 20 includes an n-type impurity such as nitrogen (N), and is of an n-type (a first conductivity type).

The first main surface 1 is a {0001} plane or a plane inclined from the {0001} plane by an off angle of 8° or less in an off direction. Preferably, the first main surface 1 is a (000-1) plane or a plane inclined from the (000-1) plane by an off angle of 8° or less in the off direction. The off direction may be, for example, a <11-20> direction or a <1-100> direction. The off angle may be, for example, 1° or more, or may be 2° or more. The off angle may be 6° or less, or may be 4° or less.

In a plan view, the silicon carbide substrate 10 has a rectangular shape having a first side 91, a second side 92, a third side 93, and a fourth side 94. The first side 91 and the second side 92 are parallel to each other, and the third side 93 and the fourth side 94 are perpendicular to the first side 91 and the second side 92. The first side 91 and the second side 92 are parallel to the Y1-Y2 direction, and the third side 93 and the fourth side 94 are parallel to the X1-X2 direction. The first side 91 is located on the X2 side relative to the second side 92, and the second side 92 is located on the X1 side relative to the first side 91. The third side 93 is located on the Y1 side relative to the fourth side 94, and the fourth side 94 is located on the Y2 side relative to the third side 93.

The silicon carbide substrate 10 has an active region 41 and a termination region 42 that surrounds the active region 41 in a plan view.

The active region 41 has a first region 101, a second region 102, and a third region 103. The first region 101 is a region where a plurality of unit cells is disposed. The second region 102 is a region that overlaps the gate pad 61 in a plan view. The third region 103 is a region where a plurality of dummy cells is disposed. The unit cells extend in the X1-X2 direction, and are arranged in the Y1-Y2 direction. The unit cells have the same dimension in the Y1-Y2 direction. Each of the unit cells includes a pair of a gate trench and a gate electrode. The unit cells are arranged at a constant pitch P1 in the Y1-Y2 direction. The dummy cells extend in the X1-X2 direction. The plurality of dummy cells may be arranged at the constant pitch P1 in the Y1-Y2 direction. The dimension of the dummy cells in the Y1-Y2 direction is the same as the dimension of the unit cells in the Y1-Y2 direction. Each of the dummy cells may include a gate electrode, but each of the dummy cells does not include a gate trench. The X1-X2 direction is an example of a first direction, and the Y1-Y2 direction is an example of a second direction.

The silicon carbide epitaxial layer 30 mainly has a drift region 31, a body region 32, a source region 33, a contact region 34, a buried region 35, a buried junction termination extension (JTE) region 36, and a surface JTE region 37. The drift region 31 are provided across the active region 41 and the termination region 42. The body region 32, the source region 33, the contact region 34, and the buried region 35 are provided in the active region 41. The buried JTE region 36 and the surface JTE region 37 are provided in the termination region 42. A portion of the contact region 34 and a portion of the buried region 35 may be provided in the termination region 42.

The drift region 31 is provided on the silicon carbide single-crystal substrate 20. The drift region 31 is located at a position closer to the first main surface 1 than the silicon carbide single-crystal substrate 20 is. The drift region 31 may be continuous with the silicon carbide single-crystal substrate 20. The drift region 31 includes an n-type impurity such as nitrogen or phosphorus (P), and is of an n-type conductivity type, for example.

The body region 32 is provided on the drift region 31. The body region 32 includes a p-type impurity such as aluminum (Al), and is of a p-type conductivity type (a second conductivity type), for example. The body region 32 is located at a position closer to the first main surface 1 than the drift region 31 is. The drift region 31 is located at a position closer to the second main surface 2 than the body region 32 is. The body region 32 contacts the drift region 31.

The source region 33 is provided on the body region 32. The source region 33 is spaced apart from the drift region 31 by the body region 32. The source region 33 includes an n-type impurity such as nitrogen or phosphorus, and is of the n-type conductivity type, for example. The source region 33 is located at a position closer to the first main surface 1 than the body region 32 is. The body region 32 is located at a position closer to the second main surface 2 than the source region 33 is. The source region 33 contacts the body region 32. The source region 33 forms the first main surface 1. The source region 33 is covered by a gate insulating film 43. The source region 33 directly contacts the gate insulating film 43.

The contact region 34 includes an p-type impurity such as aluminum, and is of the p-type conductivity type, for example. The concentration of the p-type impurity of the contact region 34 is higher than the concentration of the p-type impurity of the body region 32. The contact region 34 passes through the source region 33 and the body region 32. The contact region 34 contacts the body region 32. The contact region 34 forms the first main surface 1.

As illustrated in FIG. 14, a gate trench 5 defined by side surfaces 3 and a bottom surface 4 is provided in the first main surface 1 within the first region 101. The side surfaces 3 pass through the source region 33 and the body region 32 to reach the drift region 31. The bottom surface 4 is continuous with the side surfaces 3. The source region 33, the body region 32, and the drift region 31 contact the side surfaces 3. The bottom surface 4 is located in the drift region 31. The bottom surface 4 is, for example, a flat surface parallel to the second main surface 2. An angle θ1 of each of the side surfaces 3 with respect to a plane including the bottom surface 4 is, for example, 45° or more and 65° or less. The angle θ1 may be, for example, 50° or more. The angle θ1 may be, for example, 60° or less. Each of the side surfaces 3 preferably has a {0-33-8} plane. The {0-33-8} plane is a crystal plane in which excellent mobility is obtained.

In a plan view, the gate trench 5 extends in the X1-X2 direction parallel to the first main surface 1. A plurality of gate trenches 5 is provided at regular intervals in the Y1-Y2 direction in a plan view. The gate trench 5 is not provided in the second region 102 and the third region 103.

The buried region 35 includes an p-type impurity such as aluminum, and is of the p-type conductivity type, for example. The buried region 35 is located at a position closer to the second main surface 2 than the contact region 34 is. The contact region 34 is located at a position closer to the first main surface 1 than the buried region 35 is. The buried region 35 contacts the contact region 34. The buried region 35 is formed at a position deeper than the gate trench 5 is. The upper end surface of the buried region 35 is located at a position closer to the second main surface 2 than the bottom surface 4 of the gate trench 5 is.

The buried JTE region 36 contacts the buried region 35 in a direction parallel to the first main surface 1. The buried JTE region 36 is formed in an annular shape in a plan view. The buried JTE region 36 includes a p-type impurity such as aluminum, and is of the p-type conductivity type, for example. The buried JTE region 36 is spaced apart from the first main surface 1 and the second main surface 2. The upper end surface of the buried JTE region 36 contacts the lower end surface of the contact region 34.

The surface JTE region 37 contacts the contact region 34 in the direction parallel to the first main surface 1. The surface JTE region 37 is formed in an annular shape in a plan view. The surface JTE region 37 includes a p-type impurity such as aluminum, and is of the p-type conductivity type, for example. The surface JTE region 37 is provided above the buried JTE region 36. The surface JTE region 37 is spaced apart from the buried JTE region 36. The surface JTE region 37 is located at a position closer to the first main surface 1 than the buried JTE region 36 is. The buried JTE region 36 is located at a position closer to the second main surface 2 than the surface JTE region 37 is. The surface JTE region 37 forms the first main surface 1. A portion of the drift region 31 is located between the surface JTE region 37 and the buried JTE region 36.

The gate insulating film 43 is, for example, an oxide film. The gate insulating film 43 is composed of a material including, for example, silicon dioxide. The gate insulating film 43 contacts the side surfaces 3 and the bottom surface 4. The gate insulating film 43 contacts the drift region 31 at the bottom surface 4. The gate insulating film 43 contacts each of the source region 33, the body region 32, and the drift region 31 at the side surfaces 3. The gate insulating film 43 may contact each of the source region 33, the contact region 34, and the surface JTE region 37 at the first main surface 1.

The gate electrode 51 is provided on the gate insulating film 43. The gate electrode 51 is composed of, for example, polysilicon (poly-Si) including a conductive impurity. A portion of the gate electrode 51 is disposed inside the gate trench 5. A portion of the gate electrode 51 is disposed above the first main surface 1.

The interlayer insulating film 44 is provided in contact with the gate electrode 51 and the gate insulating film 43. The interlayer insulating film 44 is, for example, an oxide film.

The interlayer insulating film 44 is composed of a material including, for example, silicon dioxide. The interlayer insulating film 44 electrically insulates the gate electrode 51 from the contact electrode 52 and the source pad 62.

A contact hole 71 for a gate is formed in the interlayer insulating film 44. The gate electrode 51 is exposed from the interlayer insulating film 44 through the contact hole 71.

The gate pad 61 is provided on the interlayer insulating film 44, and contacts the gate electrode 51 within the contact hole 71. The gate pad 61 is composed of a material including, for example, aluminum.

A contact hole 72 for a source is formed in the interlayer insulating film 44 and the gate insulating film 43. The source region 33 and the contact region 34 in the first region 101 are exposed from the interlayer insulating film 44 and the gate insulating film 43 through the contact hole 72. The contact hole 72 is an example of a first contact hole.

A contact hole 73 for a dummy cell is formed in the interlayer insulating film 44 and the gate insulating film 43. The contact region 34 in the third region 103 is exposed from the interlayer insulating film 44 and the gate insulating film 43 through the contact hole 73. The contact hole 73 is an example of a second contact hole.

The contact electrode 52 contacts the source region 33 and the contact region 34 within the contact hole 72. The contact electrode 52 is composed of a material including, for example, nickel silicide (NiSi). The contact electrode 52 may be composed of a material including, for example, titanium, aluminum, and silicon. The contact electrode 52 is in ohmic contact with the source region 33 and the contact region 34.

The source pad 62 is provided on the interlayer insulating film 44, and contacts the contact electrode 52 within the contact hole 72. The source pad 62 is composed of a material including, for example, aluminum. The source pad 62 may include a barrier metal film (not illustrated) covering the surface of the interlayer insulating film 44. As illustrated in FIG. 1, the source pad 62 may include source pads 62A and 62B. For example, the source pad 62A is located on the X2 side with respect to the center of the silicon carbide substrate 10 in the X1-X2 direction, and the source pad 62B is located on the X1 side with respect to the center of the silicon carbide substrate 10 in the X1-X2 direction.

The gate pad 61 is located on the Y1 side of the source pad 62, and the shape of the gate pad 61 in a plan view is a rectangular shape. For example, the dimension of the gate pad 61 in the X1-X2 direction is larger than the dimension of the gate pad 61 in the Y1-Y2 direction. The source pad 62 is located on the Y2 side of the gate pad 61, and the shape of the source pad 62 in a plan view is a rectangular shape. The distance from the first side 91 to the gate pad 61 is substantially the same as the distance from the second side 92 to the gate pad 61. The distance from the third side 93 to the gate pad 61 is shorter than the distance from the fourth side 94 to the gate pad 61. The distance from the first side 91 to the source pad 62 is substantially the same as the distance from the second side 92 to the source pad 62. The distance from the third side 93 to the source pad 62 is longer than the distance from the fourth side 94 to the source pad 62. The dimension of the gate pad 61 in the X1-X2 direction may be smaller than the dimension of the source pad 62 in the X1-X2 direction. The dimension of the gate pad 61 in the Y1-Y2 direction may be smaller than the dimension of the source pad 62 in the Y1-Y2 direction. The source pad 62 is disposed to include a center line that divides the silicon carbide substrate 10 in the Y1-Y2 direction in a plan view.

The gate runner 61A extends in the Y1-Y2 direction along the first side 91. The gate runner 61B extends in the Y1-Y2 direction along the second side 92. The gate runner 61C extends in the X1-X2 direction along the third side 93. The end portion on the Y1 side of the gate runner 61A is connected to the end portion on the X2 side of the gate runner 61C. The end portion on the Y1 side of the gate runner 61B is connected to the end portion on the X1 side of the gate runner 61C. The gate runner 61A is located on the X2 side of the source pad 62A, the gate runner 61B is located on the X1 side of the source pad 62B, and the gate runner 61C is located on the Y1 side of the gate pad 61. The gate runner 61C is connected to the gate pad 61. As described, the gate pad 61 is continuous with the gate runner 61C, and the gate runners 61A and 61B are continuous with the gate runner 61C. The gate runners 61A and 61B are spaced apart from the gate pad 61 in the X1-X2 direction. The gate runner 61D is connected to the gate pad 61, and extends between the source pad 62A and the source pad 62B in the Y1-Y2 direction. The gate runners 61A, 61B, 61C, and 61D are composed of the same material as that of the gate pad 61.

The source runner 62C having an annular shape is annularly provided at the outer peripheries of the source pad 62 and the gate runners 61A, 61B, and 61C. The source runner 62C is connected to and is continuous with the source pad 62. The source runner 62C is composed of the same material as that of the source pad 62. A contact hole for the source runner 62C is annularly formed in the interlayer insulating film 44 and the gate insulating film 43. The source runner 62C is electrically connected to the contact region 34 through the annular contact hole. The contact hole 73 is a portion of the contact hole for the source runner 62C.

The passivation film 80 covers the gate pad 61, the source pad 62, and the interlayer insulating film 44. The passivation film 80 contacts the gate pad 61, the source pad 62, and the interlayer insulating film 44. The passivation film 80 also covers the gate runners 61A, 613, 61C, and 61D and the source runner 62C. The passivation film 80 also contacts the gate runners 61A, 61B, 61C, and 61D and the source runner 62C. The passivation film 80 is composed of a material including, for example, silicon nitride or polyimide. An opening 81 that exposes a portion of the upper surface of the gate pad 61 and an opening 82 that exposes a portion of the upper surface of the source pad 62 are formed in the passivation film 80.

The drain electrode 53 contacts the second main surface 2. The drain electrode 53 contacts the silicon carbide single-crystal substrate 20 at the second main surface 2. The drain electrode 53 is electrically connected to the drift region 31. The drain electrode 53 is composed of a material including, for example, nickel silicide. The drain electrode 53 may be composed of a material including titanium, aluminum, and silicon. The drain electrode 53 is in ohmic contact with the silicon carbide single-crystal substrate 20. A buffer layer that includes an n-type impurity such as nitride and is of the n-type conductivity type may be provided between the silicon carbide single-crystal substrate 20 and the drift region 31.

The second region 102 is located on the Z2 side of the gate pad 61. The third region 103 is continuous with the second region 102. The third region 103 includes a fourth region 104, a fifth region 105, a sixth region 106, and a tenth region 110. The fourth region 104 is located on the Y2 side of the second region 102, the fifth region 105 is located on the X2 side of each of the second region 102 and the fourth region 104, the sixth region 106 is located on the X1 side of each of the second region 102 and the fourth region 104, and the tenth region 110 is located on the Y1 side of the second region 102. The shapes of the fourth region 104, the fifth region 105, the sixth region 106, and the tenth region 110 in a plan view are, for example, rectangular shapes. The first region 101 is located on the Y2 side of each of the fourth region 104, the fifth region 105, and the sixth region 106. The first region 101 is provided from the vicinity of the gate runner 61A to the vicinity of the gate runner 61B in the X1-X2 direction. The first region 101 is also provided between the fifth region 105 and the gate runner 61A in a plan view and between the sixth region 106 and the gate runner 61B in a plan view. A part of or the entirety of the tenth region 110 may be located in the termination region 42.

As described above, the gate trench 5 is provided in the first region 101, but is not provided in the second region 102 and the third region 103. The source region 33 is provided in the first region 101, but is not provided in the second region 102 and the third region 103. Therefore, in the second region 102 and the third region 103, the contact region 34 forms the first main surface 1. The contact region 34 within the first region 101, the contact region 34 within the second region 102, and the contact region 34 within the third region 103 are continuous with each other along the first main surface 1. In the present embodiment, the source region 33 is provided between gate trenches 5 adjacent to each other in the Y1-Y2 direction. Each of the unit cells includes a pair of a gate trench 5 and a gate electrode 51, and the unit cells are arranged in the first region 101 at the constant pitch P1 in the Y1-Y2 direction. The contact region 34 within the second region 102 is an example of a first semiconductor region 121, and the contact region 34 within the third region 103 is an example of a second semiconductor region 122. Note that, on the Z1 side of each of the fifth region 105 and the sixth region 106, a gate electrode 51 may be provided on the contact region 34 with the gate insulating film 43 interposed therebetween.

On the Z1 side of the first region 101, contact holes 72 for a plurality of sources, formed in the interlayer insulating film 44, are arranged at a constant pitch P2 equal to the pitch P1 in the Y1-Y2 direction. Further, on the Z1 side of the third region 103, contact holes 73 for a plurality of dummy cells, formed in the interlayer insulating film 44, are arranged at the pitch P2 in the Y1-Y2 direction. A contact hole 72 and a contact hole 73 adjacent to each other in the Y1-Y2 direction are also arranged at the pitch P2. On the Z1 side of the second region 102, contact holes 71 for gates are formed in the interlayer insulating film 44, but the contact holes 72 for the sources and the contact holes 73 for the dummy cells are not formed. Contact holes 71 for gates are also formed in the interlayer insulating film 44 between gate electrodes 51 and the gate runners 61A, 61B, 61C, and 61D. Note that, in FIG. 3, a contact hole 71 is provided for each of gate electrodes 51; however, the contact hole 71 may be formed so as to be continuous with each of the gate electrodes 51. In such a case, the electric resistance between the gate electrodes 51 and the gate runner 61D can be reduced. The same applies to the gate runners 61A, 61B, and 61C.

Contact holes 73 are also formed in the interlayer insulating film 44 and the gate insulating film 43 between the tenth region 110 and the source runner 62C.

Contact electrodes 52 contact the contact region 34 within the contact holes 73. The contact electrodes 52 are in in ohmic contact with the contact region 34. The source pad 62 and the source runner 62C contact the contact electrodes 52 within the contact holes 73.

In the first embodiment, the third region 103 continuous with the second region 102 is provided, and the contact region 34 is continuous across the second region 102 and the third region 103. Accordingly, the contact resistance between the source pad 62 and the contact region 34 is reduced, and even if a surge occurs, the electric field concentration in the interlayer insulating film 44 within the second region 102 can be reduced.

Further, on the Z2 side of the third region 103, the contact holes 73 for the dummy cells, formed in the interlayer insulating film 44, are arranged at the same pitch P2 as the contact holes 72 for the sources of the unit cells. Therefore, micro-loading when the contact holes 72 and 73 are formed can be suppressed, and variations in characteristics can be suppressed.

Further, the contact region 34 within the first region 101 and the contact region 34 within the third region 103 are continuous with each other. Therefore, the contact region 34 within the first region 101 and the contact region 34 within the third region 103 can be easily controlled to have the same electric potential.

The dimension, in the Y1-Y2 direction, of the contact region 34 within the fourth region 104 is preferably greater than or equal to the pitch P1 of the unit cells, and is more preferably twice or more the pitch P1. This is because the contact resistance can be further reduced.

The area of the contact region 34 within fifth region 105 is preferably larger than or equal to the area of the contact region 34 within the fourth region 104. Similarly, the area of the contact region 34 within the sixth region 106 is preferably larger than or equal to the area of the contact region 34 within the fourth region 104. This is because the contact resistance can be further reduced.

Note that the third region 103 does not necessarily include the tenth region 110. The same applies to embodiments as will be described below.

### Second Embodiment

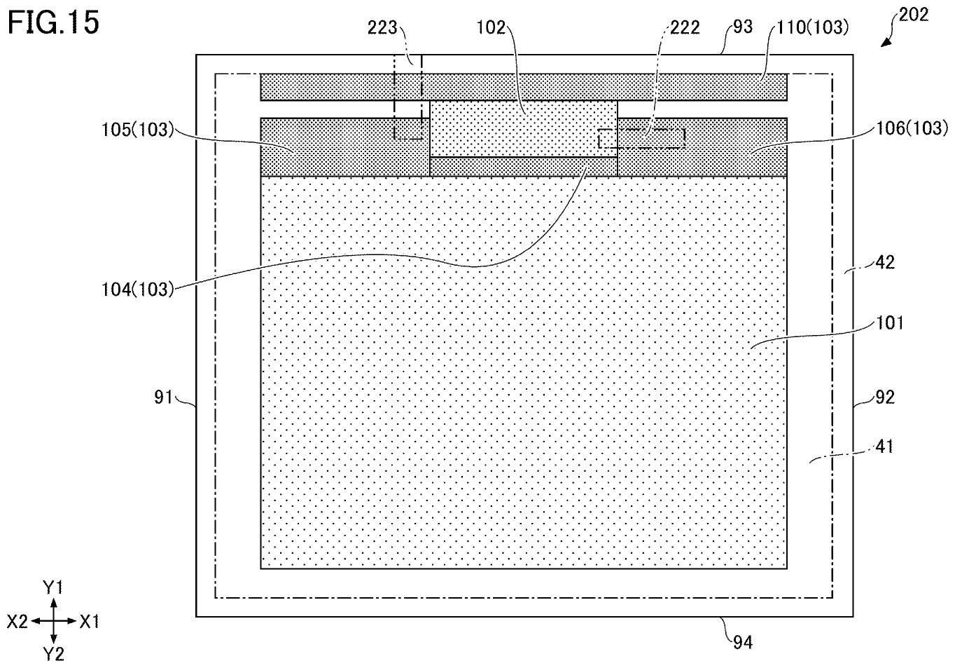

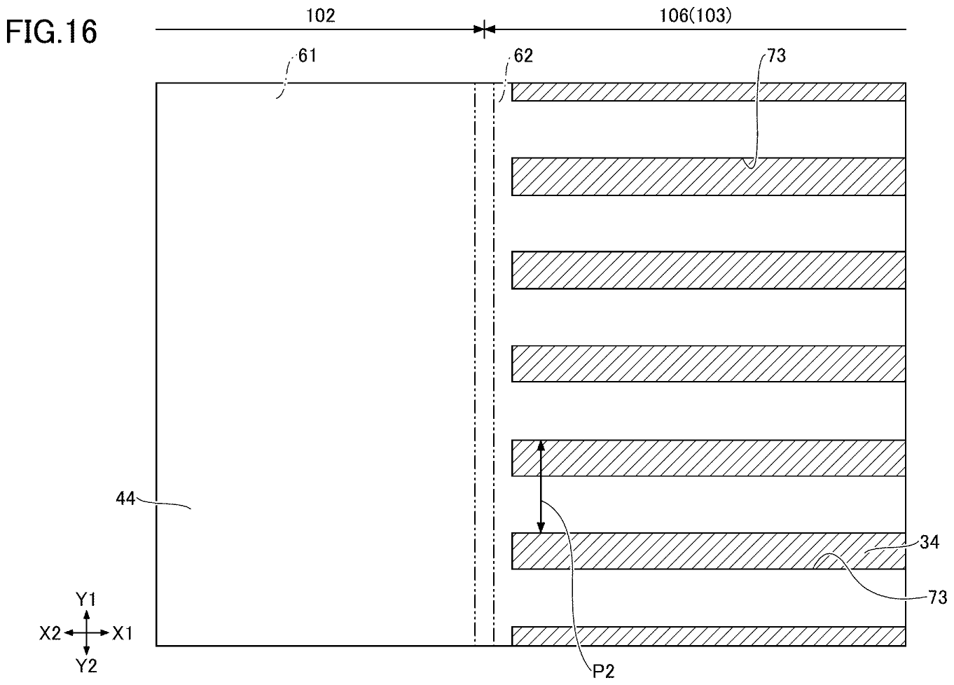

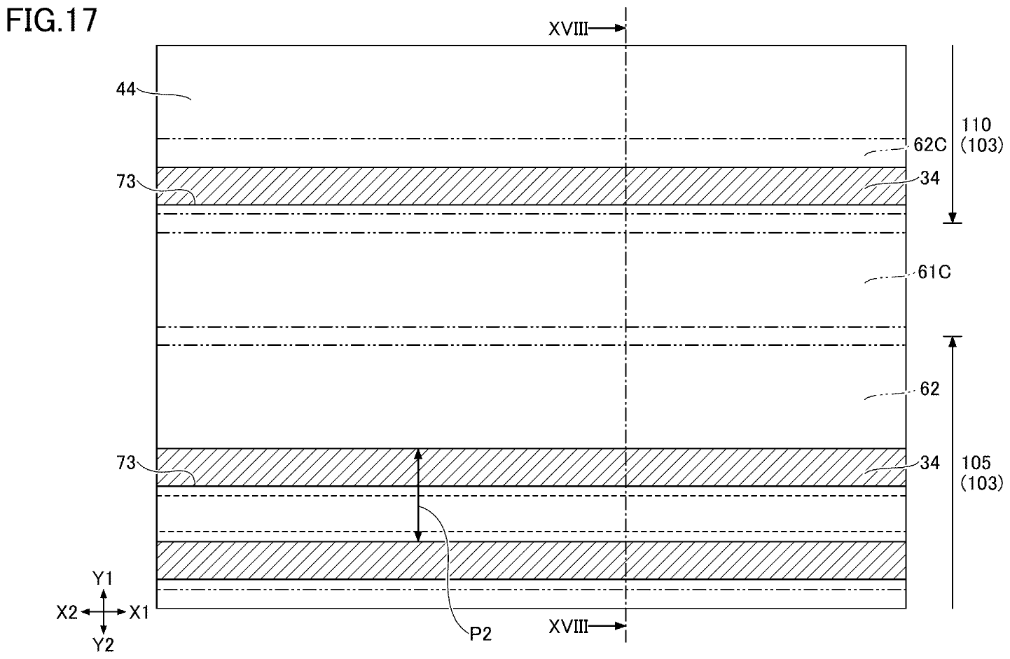

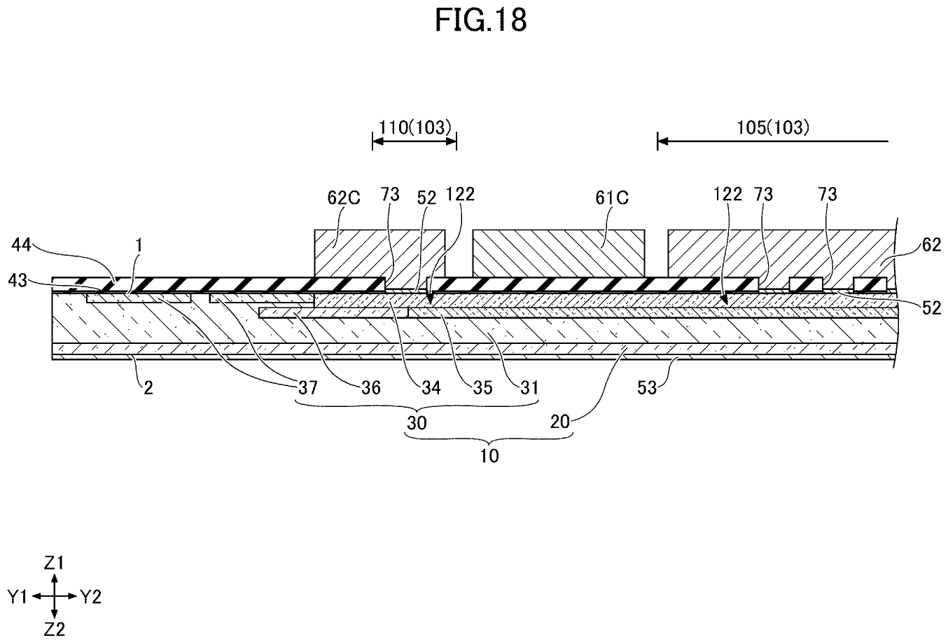

Next, a second embodiment will be described. The second embodiment differs from the first embodiment mainly in the layout of a first region 101 and a third region 103. FIG. 15 is a diagram illustrating regions in a silicon carbide substrate of a silicon carbide semiconductor device according to the second embodiment. FIG. 16 is a top view illustrating a region 222 of FIG. 15 when a passivation film, a gate pad, and a source pad are transparently viewed. FIG. 17 is a top view illustrating a region 223 of FIG. 15 when the passivation film, the gate pad, and the source pad are transparently viewed. FIG. 18 is a cross-sectional view illustrating the silicon carbide semiconductor device according to the second embodiment. FIG. 18 corresponds to a cross-sectional view along the line XVIII-XVIII of FIG. 17. The passivation film is not depicted in FIG. 18.

As illustrated in FIG. 15 to FIG. 18, in a MOSFET 202 according to the second embodiment, the first region 101 is located only on the Y2 side of a fourth region 104, a fifth region 105, a sixth region 106. The fifth region 105 extends to the vicinity of the gate runner 61A and the sixth region 106 extends to the vicinity of the gate runner 61B in a plan view. Further, on the Z1 side of the fifth region 105 and the sixth region 106, the entire upper surface (surface on the Z1 side) of a gate insulating film 43 contacts the lower surface (surface on the Z2 side) of an interlayer insulating film 44. That is, no gate electrode 51 is provided on the Z1 side of the fifth region 105 and the sixth region 106.

Other configurations are the same as those of the first embodiment.

According to the second embodiment, the same effects as those of the first embodiment can be obtained. Further, according to the second embodiment, no gate electrode 51 is provided on the Z1 side of the fifth region 105 and the sixth region 106, and thus, the parasitic capacitance between a gate electrode 51 and a source pad 62 can be reduced.

### Third Embodiment

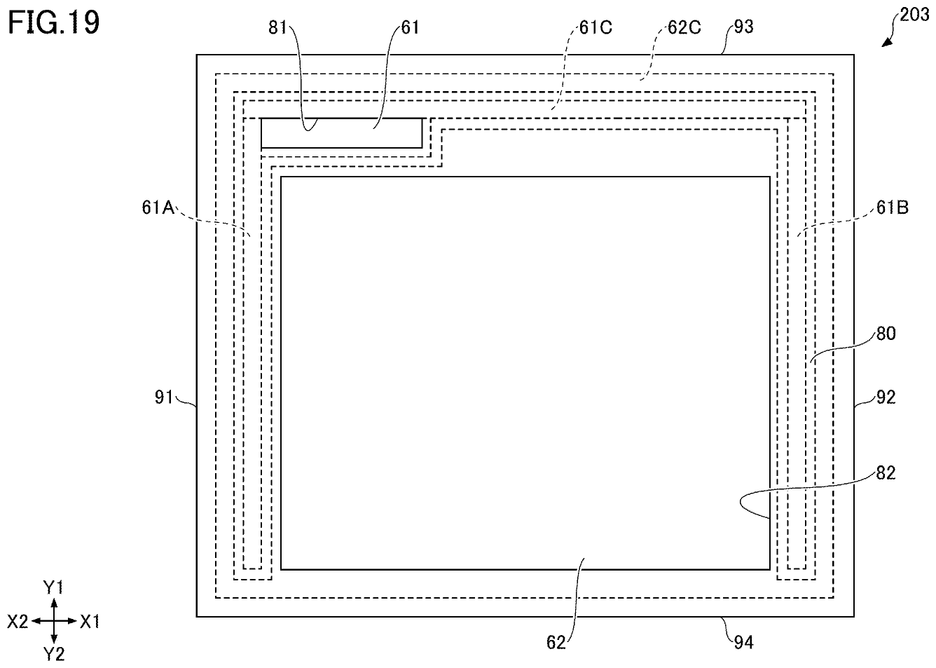

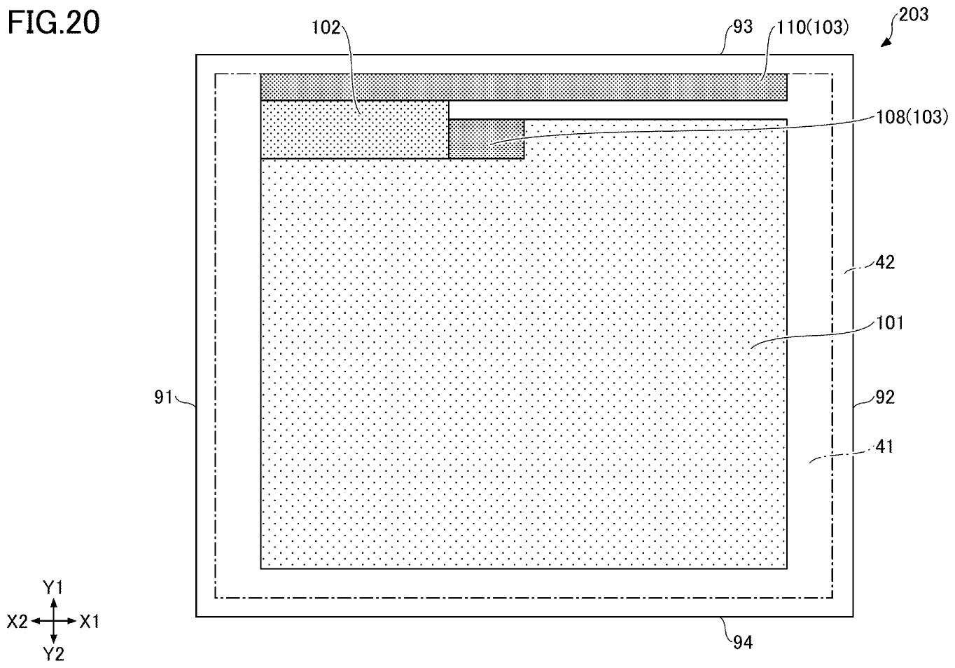

Next, a third embodiment will be described. The third embodiment differs from the first embodiment mainly in the arrangement of a gate pad. FIG. 19 is a top view illustrating a silicon carbide semiconductor device according to the third embodiment. FIG. 20 is a diagram illustrating regions in a silicon carbide substrate of the silicon carbide semiconductor device according to the third embodiment.

As illustrated in FIG. 19 and FIG. 20, in a MOSFET 203 according to the third embodiment, a gate pad 61 is connected to the gate runner 61A and the gate runner 61C. The gate pad 61 is continuous with the gate runner 61A and the gate runner 61C, and includes an intersection between the gate runner 61A and the gate runner 61C. The gate runner 61B is spaced apart from the gate pad 61 in the X1-X2 direction. A source pad 62 is not divided into two source pads 62A and 62B, and no gate runner 61D is provided.

Further, a third region 103 includes an eighth region 108 instead of the fourth region 104, the fifth region 105, and the sixth region 106. The shape of the eighth region 108 in a plane view is, for example, a rectangular shape. The eighth region 108 is disposed along the side, closest to the second side 92, of the gate pad 61, and is spaced apart from the gate runner 61B. The eighth region 108 has the same configuration as that of the sixth region 106 according to the first embodiment. A first region 101 is located on the Y2 side of a second region 102 and the eighth region 108. The first region 101 is provided so as to extend from the vicinity of the gate runner 61A to the vicinity of the gate runner 61B in the X1-X2 direction. The first region 101 is also provided between the eighth region 108 and the gate runner 61B in a plan view.

Other configurations are the same as those of the first embodiment.

According to the third embodiment, the same effects as those of the first embodiment can be obtained. Further, according to the third embodiment, the degree of freedom in the arrangement of the gate pad 61 can be improved.

### Fourth Embodiment

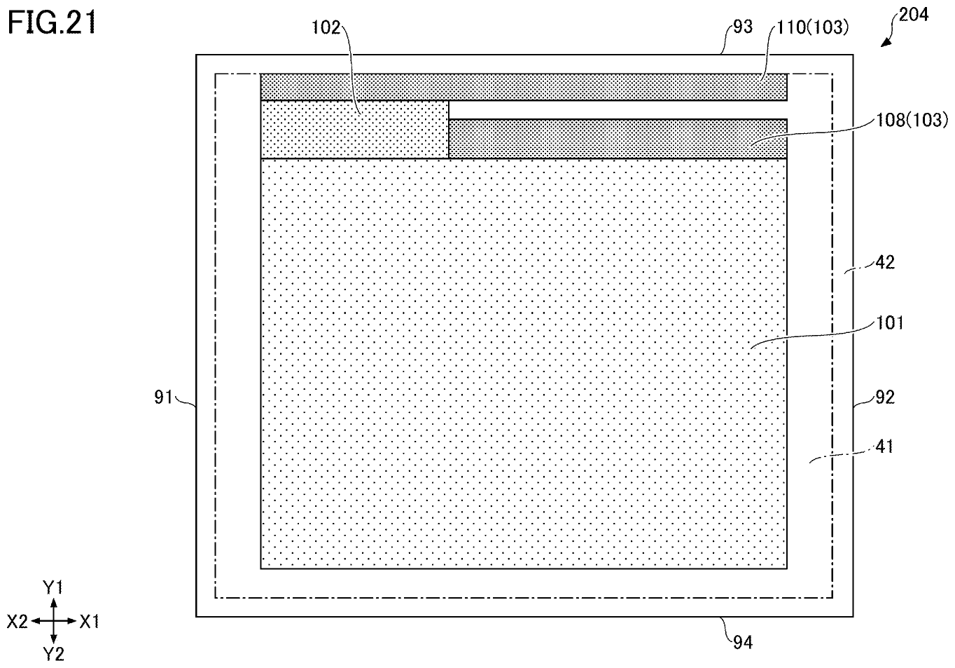

Next, a fourth embodiment will be described. The fourth embodiment differs from the third embodiment mainly in the layout of a first region 101 and a third region 103. FIG. 21 is a diagram illustrating regions in a silicon carbide substrate of a silicon carbide semiconductor device according to the fourth embodiment.

As illustrated in FIG. 21, in a MOSFET 204 according to the fourth embodiment, the first region 101 is located only on the Y2 side of a second region 102 and an eighth region 108. The eighth region 108 extends to the vicinity of the gate runner 61B (see FIG. 19) in a plan view. Further, on the Z1 side of the eighth region 108, the entire upper surface (surface on the Z1 side) of a gate insulating film 43 contacts the lower surface (surface on the Z2 side) of an interlayer insulating film 44. That is, no gate electrode 51 is provided on the Z1 side of the eighth region 108.

Other configurations are the same as those of the third embodiment.

According to the fourth embodiment, the same effects as those of the third embodiment can be obtained. Further, according to the fourth embodiment, no gate electrode 51 is provided on the Z1 side of the eighth region 108, and thus, the parasitic capacitance between a gate electrode 51 and a source pad 62 can be reduced.

### Fifth Embodiment

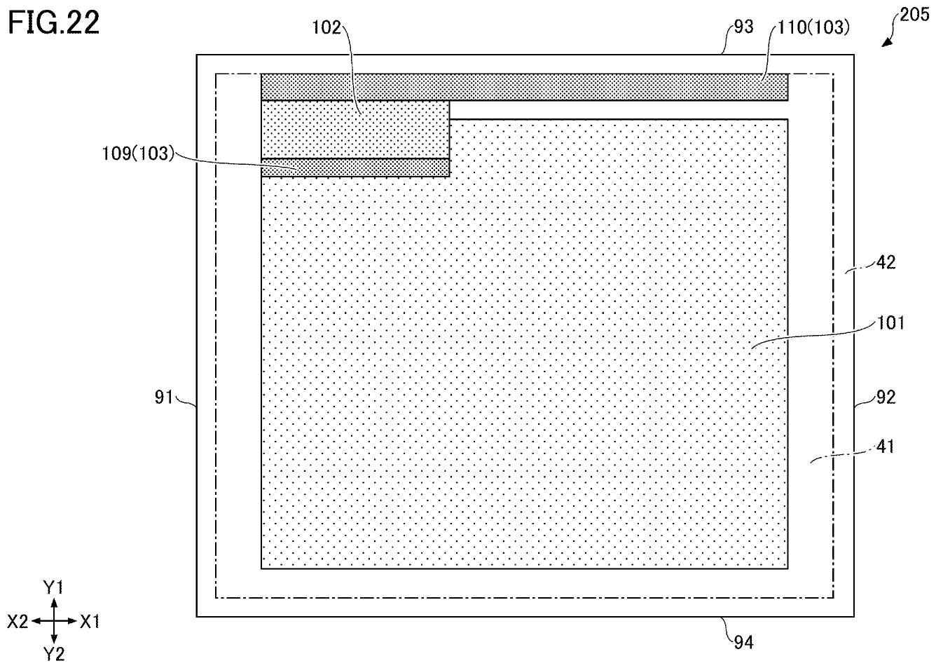

Next, a fifth embodiment will be described. The fifth embodiment differs from the third embodiment mainly in the layout of a first region 101 and a third region 103. FIG. 22 is a diagram illustrating regions in a silicon carbide substrate of a silicon carbide semiconductor device according to the fifth embodiment.

As illustrated in FIG. 22, in a MOSFET 205 according to the fifth embodiment, the third region 103 includes a ninth region 109 instead of the eighth region 108. The ninth region 109 is disposed along the side, closest to the fourth side 94, of a gate pad 61 in a plan view. The ninth region 109 has the same configuration as that of the fourth region 104 according to the first embodiment. The first region 101 is also provided between the gate runner 61B (see FIG. 19) and a second region 102 and the ninth region 109.

Other configurations are the same as those of the third embodiment.

According to the fifth embodiment, the same effects as those of the third embodiment can be obtained. Further, according to the fifth embodiment, the third region 103 is connected to the second region 102 in a wide range, and thus, the contact resistance can be further reduced as compared to the third embodiment.

### Sixth Embodiment

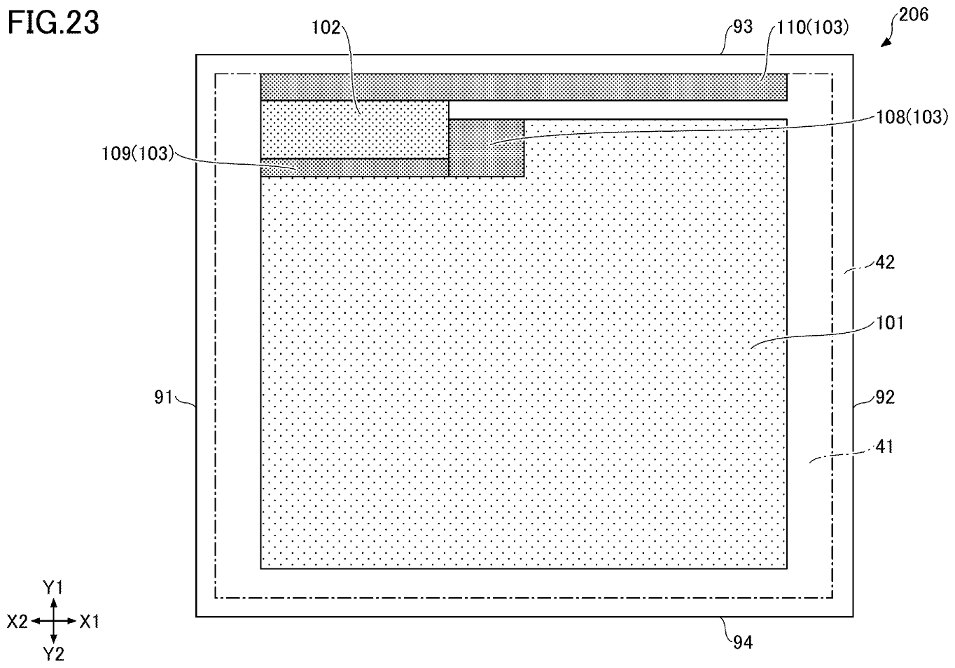

Next, a sixth embodiment will be described. The sixth embodiment has a configuration in which the third embodiment and the fifth embodiment are combined. FIG. 23 is a diagram illustrating regions in a silicon carbide substrate of a silicon carbide semiconductor device according to the sixth embodiment.

As illustrated in FIG. 23, in a MOSFET 206 according to the sixth embodiment, a third region 103 includes an eighth region 108 in addition to a tenth region 110 and a ninth region 109. The eighth region 108 is disposed along the sides, closest to the second side 92, of the gate pad 61 and of the ninth region 109, and similar to the third embodiment, the eighth region 108 is spaced apart from the gate runner 61B.

Other configurations are the same as those of the fifth embodiment.

According to the sixth embodiment, the same effects as those of the fifth embodiment can be obtained. Further, according to the sixth embodiment, the third region 103 is connected to the second region 102 in a wide range, and thus, the contact resistance can be further reduced as compared to the fifth embodiment.

### Seventh Embodiment

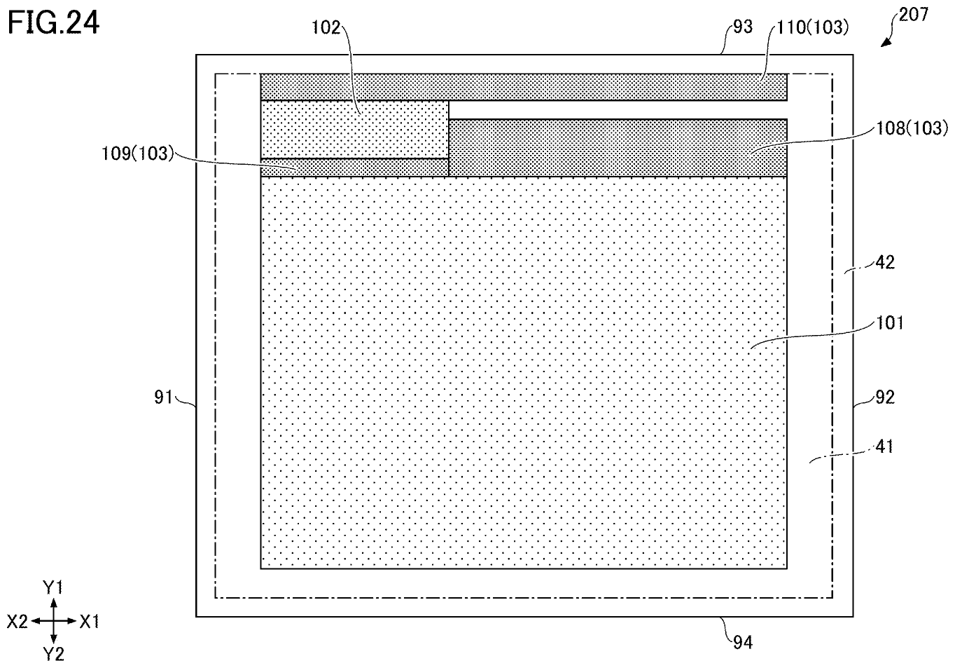

Next, a seventh embodiment will be described. The seventh embodiment has a configuration in which the fourth embodiment and the fifth embodiment are combined. FIG. 24 is a diagram illustrating regions in a silicon carbide substrate of a silicon carbide semiconductor device according to the seventh embodiment.

As illustrated in FIG. 24, in a MOSFET 207 according to the seventh embodiment, a first region 101 is located only on the Y2 side of a second region 102 and an eighth region 108. The eighth region 108 extends to the vicinity of the gate runner 61B (see FIG. 19) in a plan view. Further, on the Z1 side of the eighth region 108, the entire upper surface (surface on the Z1 side) of a gate insulating film 43 contacts the lower surface (surface on the Z2 side) of an interlayer insulating film 44. That is, no gate electrode 51 is provided on the Z1 side of the eighth region 108.

Other configurations are the same as those of the sixth embodiment.

According to the seventh embodiment, the same effects as those of the sixth embodiment can be obtained. Further, according to the seventh embodiment, no gate electrode 51 is provided on the Z1 side of the eighth region 108, and thus, the parasitic capacitance between a gate electrode 51 and a source pad 62 can be reduced.

On the Z1 side of the ninth region 109, the entire upper surface (surface on the Z1 side) of the gate insulating film 43 may contact the lower surface (surface on the Z2 side) of the interlayer insulating film 44. In such a case, the parasitic capacitance between the gate electrode 51 and the source pad 62 can be further reduced.

### Eighth Embodiment

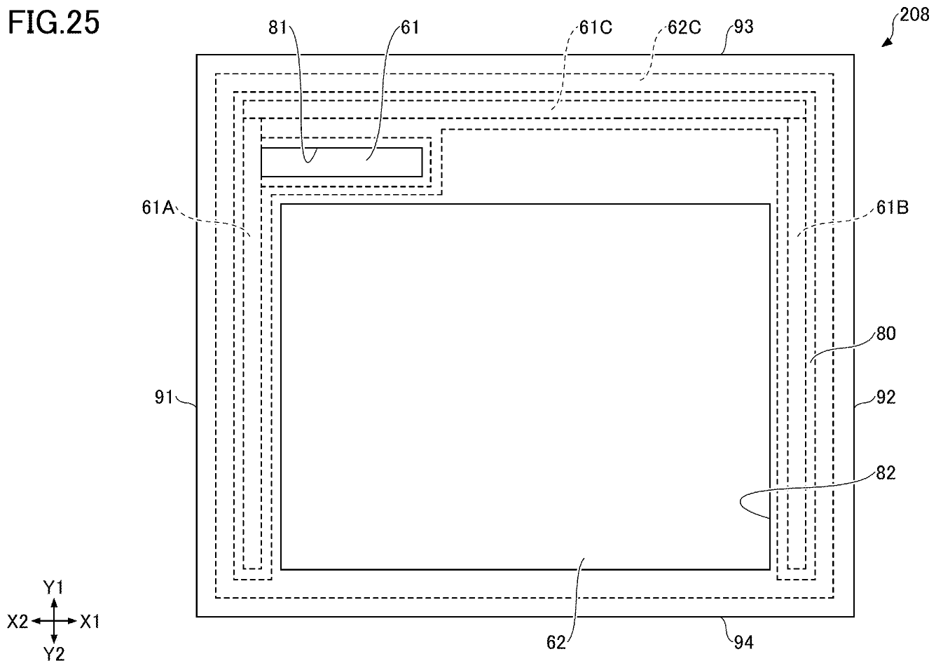

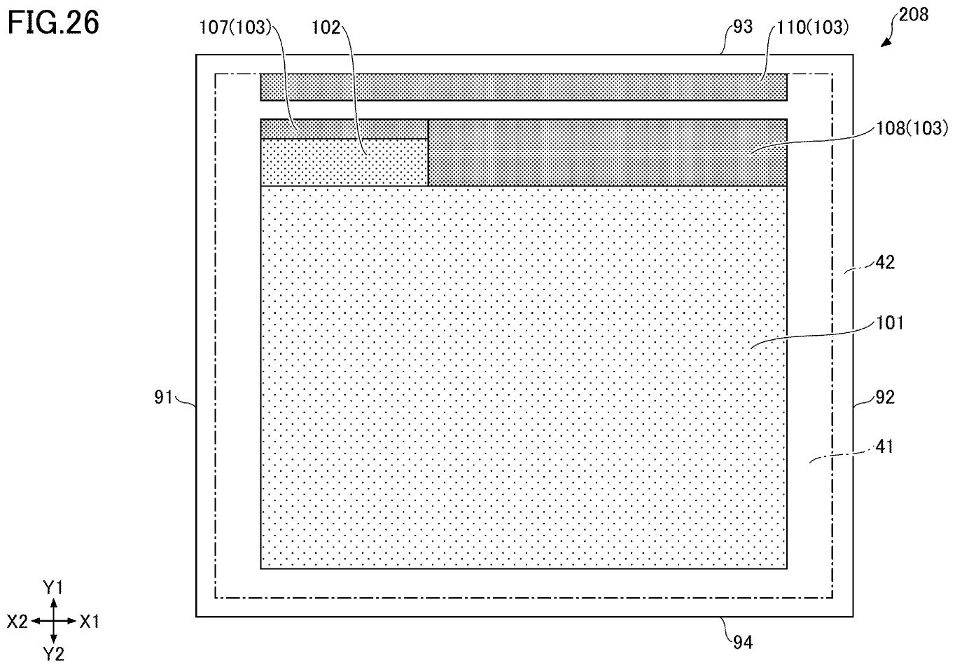

Next, an eighth embodiment will be described. The eighth embodiment differs from the fourth embodiment mainly in the arrangement of a gate pad. FIG. 25 is a top view illustrating a silicon carbide semiconductor device according to the eighth embodiment. FIG. 26 is a diagram illustrating regions in a silicon carbide substrate of the silicon carbide semiconductor device according to the eighth embodiment.

As illustrated in FIG. 25 and FIG. 26, in a MOSFET 208 according to the eighth embodiment, a gate pad 61 is spaced apart from the gate runner 61C toward the Y2 side. The gate pad 61 is connected to the gate runner 61A. A third region 103 includes a seventh region 107 between a second region 102 and the gate runner 61C. Similar to the fourth embodiment, the third region 103 also includes a tenth region 110 and an eighth region 108. The eighth region 108 is also located on the X1 side of the seventh region 107. The seventh region 107 has the same configuration as that of the ninth region 109 according to the seventh embodiment.

Other configurations are the same as those of the third embodiment.

According to the eighth embodiment, the same effects as those of the fourth embodiment can be obtained.

### Ninth Embodiment

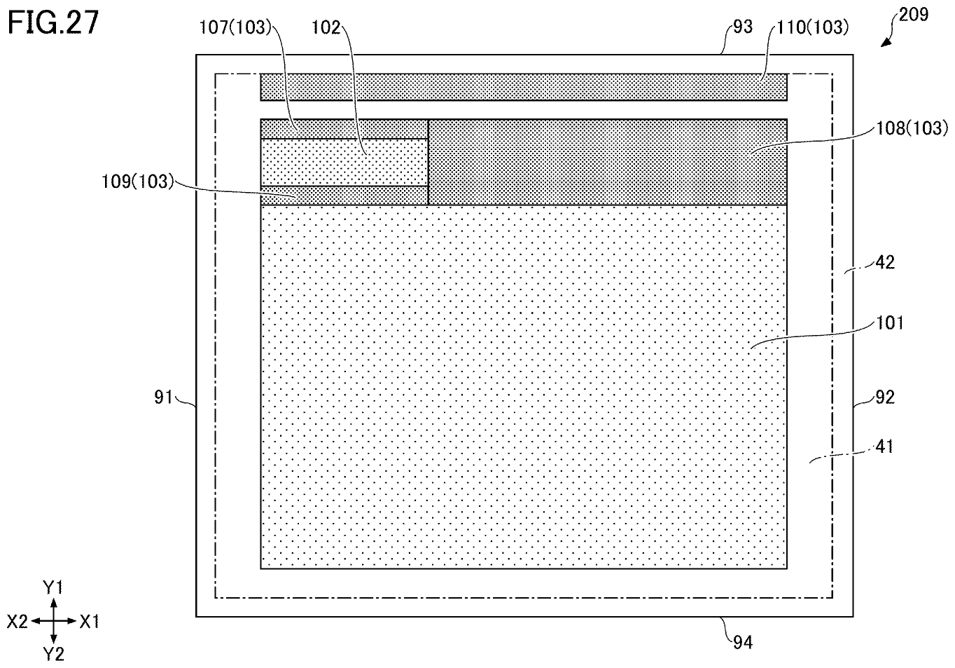

Next, a ninth embodiment will be described. The ninth embodiment differs from the eighth embodiment mainly in the layout of a first region 101 and a third region 103. FIG. 27 is a diagram illustrating regions in a silicon carbide substrate of a silicon carbide semiconductor device according to the ninth embodiment.

As illustrated in FIG. 27, in a MOSFET 209 according to the ninth embodiment, the third region 103 includes a ninth region 109 in addition to a tenth region 110, an eighth region 108, and a seventh region 107. The eighth region 108 is also located on the X1 side of the ninth region 109.

Other configurations are the same as those of the eighth embodiment.

According to the ninth embodiment, the same effects as those of the eighth embodiment can be obtained. Further, according to the ninth embodiment, the third region 103 is connected to the second region 102 in a wide range, and thus, the contact resistance can be further reduced as compared to the eighth embodiment.

### Tenth Embodiment

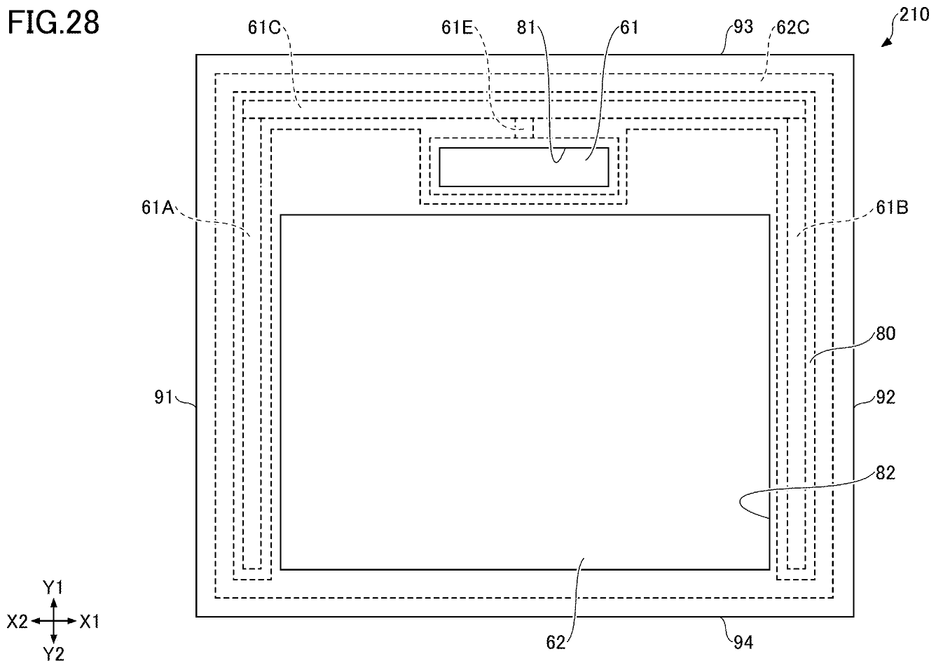

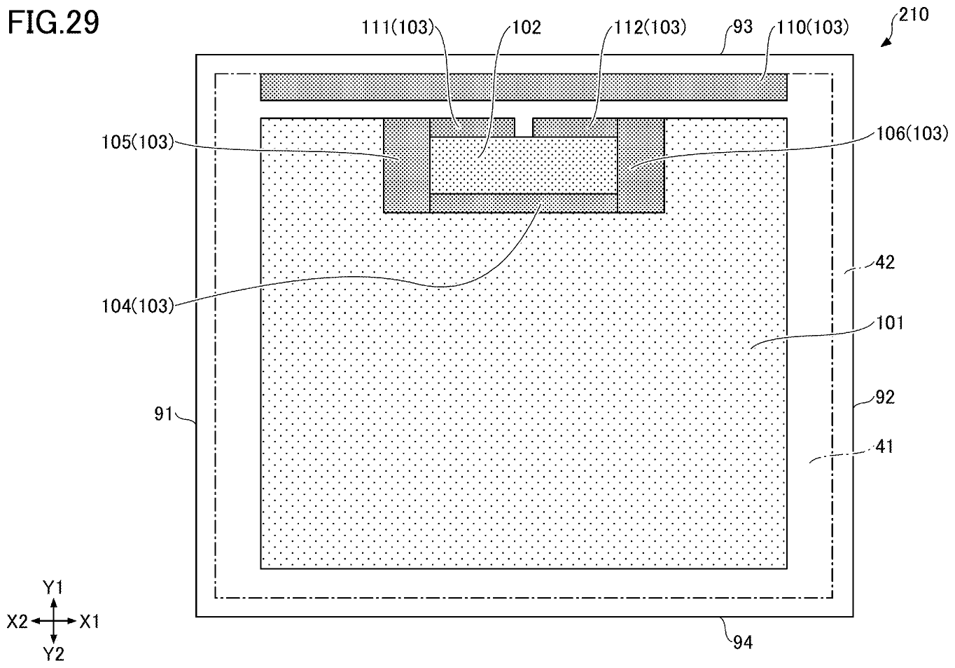

Next, a tenth embodiment will be described. The tenth embodiment differs from the first embodiment mainly in the arrangement of a gate pad. FIG. 28 is a top view illustrating a silicon carbide semiconductor device according to the tenth embodiment. FIG. 29 is a diagram illustrating regions in a silicon carbide substrate of the silicon carbide semiconductor device according to the tenth embodiment.

As illustrated in FIG. 28 and FIG. 29, in a MOSFET 210 according to the tenth embodiment, a gate pad 61 is spaced apart from the gate runner 61C toward the Y2 side. The MOSFET 210 includes a gate runner 61E connecting the gate runner 61C and the gate pad 61. A third region 103 includes an eleventh region 111 and a twelfth region 112. The eleventh region 111 is located on the X2 side of the gate runner 61E and is located between a second region 102 and the gate runner 61C. The twelfth region 112 is located on the X1 side of the gate runner 61E and is located between the second region 102 and the gate runner 61C. The gate runner 61E is composed of the same material as that of the gate pad 61. The eleventh region 111 and the twelfth region 112 have the same configuration as that of the seventh region 107 according to the eighth embodiment. The gate runner 61E is an example of a fourth gate runner. The eleventh region 111 and the twelfth region 112 are an example of a seventh region.

Other configurations are the same as those of the first embodiment.

According to the tenth embodiment, the same effects as those of the first embodiment can be obtained. Further, according to the tenth embodiment, the degree of freedom in the arrangement of the gate pad 61 can be improved.

### Eleventh Embodiment

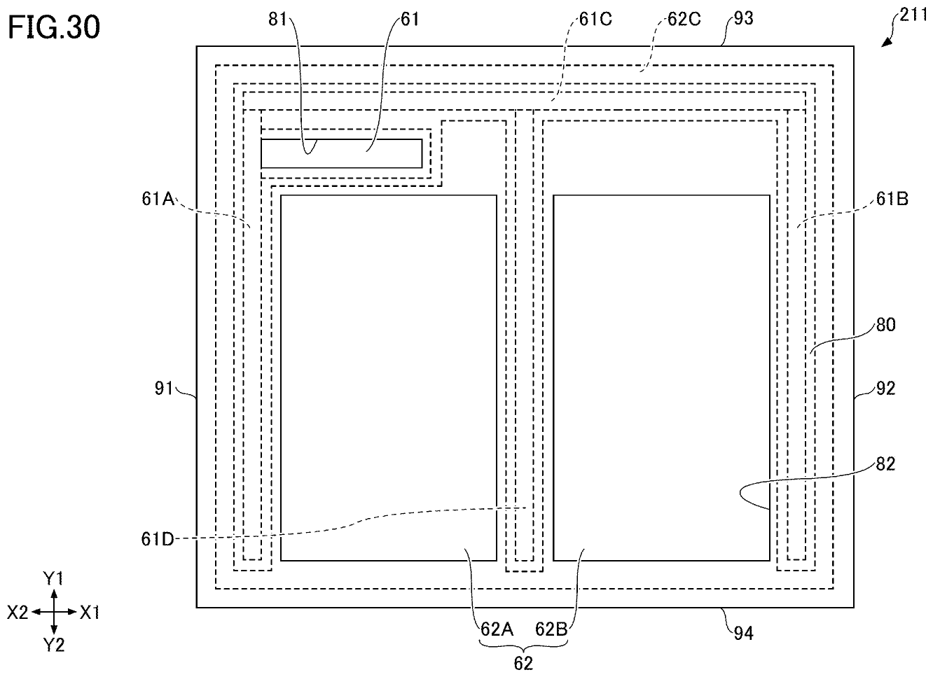

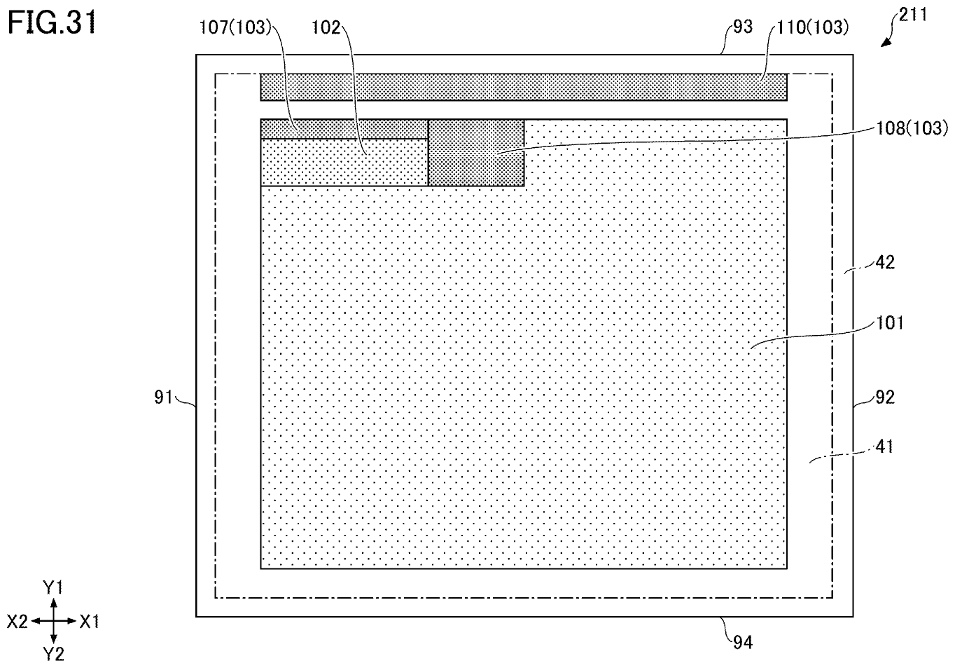

Next, an eleventh embodiment will be described. The eleventh embodiment is different from the eighth embodiment mainly in the arrangement of gate runners. FIG. 30 is a top view illustrating a silicon carbide semiconductor device according to the eleventh embodiment. FIG. 31 is a diagram illustrating regions in a silicon carbide substrate of the silicon carbide semiconductor device according to the eleventh embodiment.

As illustrated in FIG. 30 and FIG. 31, a MOSFET 211 according to the eleventh embodiment includes a gate runner 61D. The gate runner 61D is connected to the gate runner 61C. Further, similar to the first embodiment, a source pad 62 includes source pads 62A and 62B. An eighth region 108 is located on the gate runner 61A side (X2 side) with respect to the gate runner 61D in a plan view.

Other configurations are the same as those of the eighth embodiment.

According to the eleventh embodiment, the same effects as those of the eighth embodiment can be obtained.

### First Region According to Modification

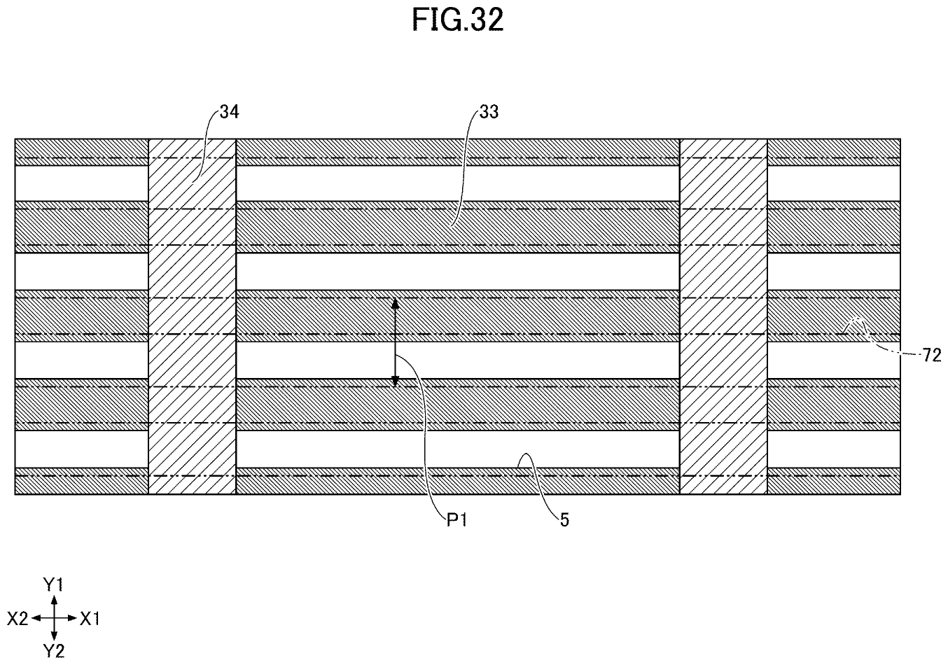

Next, a first region according to a modification will be described. In this modification, a configuration of unit cells differs from the first embodiment and the like. FIG. 32 is a top view illustrating the first region according to the modification. Similar to FIG. 4, FIG. 32 depicts a configuration of a first main surface of a silicon carbide substrate.

In this modification, in a first region 101, a plurality of gate trenches 5 is formed between two gate runners adjacent to each other in the X1-X2 direction. Further, in the first region 101, a contact region 34 is provided between gate trenches 5 adjacent to each other in the X1-X2 direction, and extends in the Y1-Y2 direction.

Although the embodiments have been described in detail above, the present disclosure is not limited to the specific embodiments, and various modifications and changes can be made within the scope described in the claims.

### DESCRIPTION OF THE REFERENCE NUMERALS

1 first main surface
2 second main surface
3 side surface
4 bottom surface
5 gate trench
10 silicon carbide substrate
20 silicon carbide single-crystal substrate
30 silicon carbide epitaxial layer
31 drift region
32 body region
33 source region
34 contact region
35 buried region
36 buried JTE region
37 surface JTE region
41 active region
42 termination region
43 gate insulating film
44 interlayer insulating film
51 gate electrode
52 contact electrode
53 drain electrode
61 gate pad
61A, 61B, 61C, 61D, 61E gate runner
62, 62A, 62B source pad
62C source runner
63 gate insulating film
71, 72, 73 contact hole
80 passivation film
81, 82 opening
91 first side
92 second side
93 third side
94 fourth side
101 first region
102 second region
103 third region
104 fourth region
105 fifth region
106 sixth region
107 seventh region
108 eighth region
109 ninth region
110 tenth region
111 eleventh region
112 twelfth region
121 first semiconductor region
122 second semiconductor region
201, 202, 203, 204, 205, 206, 207, 208, 209, 210,
211 MOSFET
221, 222, 223, 224 region

1. A silicon carbide semiconductor device comprising:
a silicon carbide substrate having a first main surface; and
a gate pad and a source pad, the gate pad and the source pad being provided above the first main surface,
wherein, in a plan view from a direction perpendicular to the first main surface, the silicon carbide substrate includes
a first region that includes a plurality of unit cells,
a second region that overlaps the gate pad, and
a third region that is continuous with the second region,
each of the unit cells includes
a drift region that is of a first conductivity type,
a body region that is of a second conductivity type different from the first conductivity type,
a source region that is provided along the first main surface, is spaced apart from the drift region by the body region, and is of the first conductivity type,
a contact region that is provided along the first main surface, is electrically connected to the body region, and is of the second conductivity type,
a gate electrode electrically connected to the gate pad, and
a gate insulating film provided between
the gate electrode and
the drift region, the body region, and the source region,
the second region has a first semiconductor region that is of the second conductivity type,
the third region has a second semiconductor region that is of the second conductivity type,
the first semiconductor region and the second semiconductor region are continuous with each other along the first main surface,
the silicon carbide semiconductor device further includes an interlayer insulating film provided between the first semiconductor region and the gate pad, and
the source region, the contact region, and the second semiconductor region are electrically connected to the source pad.

2. The silicon carbide semiconductor device according to claim 1, wherein the contact region and the second semiconductor region are continuous with each other along the first main surface.

3. The silicon carbide semiconductor device according to claim 1, wherein, in the plan view, the unit cells extend in a first direction and are arranged at a first pitch in a second direction that is perpendicular to the first direction, and
a dimension of the second semiconductor region in a direction away from the second region is greater than or equal to the first pitch.

4. The silicon carbide semiconductor device according to claim 3, wherein the dimension of the second semiconductor region in the direction away from the second region is twice or more the first pitch.

5. The silicon carbide semiconductor device according to claim 3, wherein the third region includes a fourth region located between the first region and the second region in the plan view, and
a dimension, in the second direction, of the second semiconductor region within the fourth region is greater than or equal to the first pitch.

6. The silicon carbide semiconductor device according to claim 5, wherein the dimension, in the second direction, of the second semiconductor region within the fourth region is twice or more the first pitch.

7. The silicon carbide semiconductor device according to claim 5, wherein, in the plan view, the third region includes a fifth region located on one side, in the first direction, of the second region and of the fourth region, and
an area of the second semiconductor region within the fifth region is larger than or equal to an area of the second semiconductor region within the fourth region.

8. The silicon carbide semiconductor device according to claim 5, wherein, in the plan view, the third region includes a sixth region located on an opposite side, in the first direction, of the second region and of the fourth region, and
an area of the second semiconductor region within the sixth region is larger than or equal to an area of the second semiconductor region within the fourth region.

9. The silicon carbide semiconductor device according to claim 3, wherein the interlayer insulating film is formed in the first region and the third region,
for each of the unit cells, a first contact hole is formed in the interlayer insulating film within the first region, the first contact hole reaching the source region and the contact region,
a second contact hole is formed in the interlayer insulating film within the third region, the second contact hole reaching the second semiconductor region, and
the first contact hole and the second contact hole are arranged at a predetermined pitch in the second direction.

10. The silicon carbide semiconductor device according to claim 1, wherein, in the plan view, the silicon carbide substrate has a rectangular shape having a first side, a second side, a third side, and a fourth side, the first side and the second side being parallel to each other, and the third side and the fourth side being perpendicular to the first side and the second side,
the silicon carbide semiconductor device further includes
a first gate runner extending along the first side,
a second gate runner extending along the second side, and
a third gate runner continuous with the first gate runner and the second gate runner and extending along the third side,
the gate pad is continuous with the first gate runner, and
the second gate runner is spaced apart from the gate pad in a direction parallel to the third side.

11. The silicon carbide semiconductor device according to claim 10, wherein the gate pad includes an intersection between the first gate runner and the third gate runner, and is continuous with the first gate runner and the third gate runner.

12. The silicon carbide semiconductor device according to claim 10, wherein the third gate runner is spaced apart from the gate pad in a direction parallel to the first side.

13. The silicon carbide semiconductor device according to claim 12, wherein the third region includes a seventh region located along a side, closest to the third side, of the gate pad in the plan view, and
the seventh region is continuous with the third gate runner.

14. The silicon carbide semiconductor device according to claim 10, wherein the third region includes an eighth region located along a side, closest to the second side, of the gate pad in the plan view, and
the eighth region is spaced apart from the second gate runner.

15. The silicon carbide semiconductor device according to claim 10, wherein the third region includes an eighth region located along a side, closest to the second side, of the gate pad in the plan view, and the eighth region is continuous with the second gate runner.

16. The silicon carbide semiconductor device according to claim 10, wherein the third region includes a ninth region located along a side, closest to the fourth side, of the gate pad in the plan view.

17. The silicon carbide semiconductor device according to claim 1, wherein the silicon carbide substrate has a rectangular shape having a first side, a second side, a third side, and a fourth side in the plan view, the first side and the second side being parallel to each other, and the third side and the fourth side being perpendicular to the first side and the second side,
the third region surrounds the gate pad in the plan view,
the silicon carbide semiconductor device further includes
a first gate runner extending along the first side,
a second gate runner extending along the second side, and
a third gate runner continuous with the first gate runner and the second gate runner and extending along the third side, and
a fourth gate runner connecting the third gate runner and the gate pad.
